(19) United States
(12) Patent Application Publication
(10) Pub. No.: US 2023/0244076 A1
(43) Pub. Date: Aug. 3, 2023

(54) GLASS-SUBSTRATE-BASED MEMS MIRROR DEVICE AND METHOD FOR ITS PRODUCTION

(71) Applicant: OQMENTED GMBH, Itzehoe (DE)

(72) Inventors: Stephan MARAUSKA, Kaltenkirchen (DE); Ulrich HOFMANN, Itzehoe (DE); Thomas VON WANTOCH, Kiel (DE); Fabian SCHWARZ, Itzehoe (DE)

(21) Appl. No.: 18/002,689

(22) PCT Filed: Jun. 22, 2021
(86) PCT No.: PCT/EP2021/067010

§ 371 Date: Dec. 21, 2022

(30) Foreign Application Priority Data
Jun. 23, 2020 (DE) 10 2020 116 511.0

(51) Int. Cl. G02B 26/08; G02B 6/35; B81B 7/02

(52) U.S. Cl. CPC G02B 26/0858; G02B 6/3518; B81B 7/02; B81B 2201/042

(57) ABSTRACT

The invention relates to a glass substrate-based MEMS mirror device for variable deflection of an incident electromagnetic beam, as well as a method for its production. The MEMS mirror device has a disk-shaped first glass substrate structured into a plurality of subregions with a mirror subregion formed at least partially as a MEMS mirror for reflecting electromagnetic radiation and a frame subregion surrounding the mirror subregion at least in sections. The mirror subregion is designed as a subregion of the first glass substrate suspended so as to be capable of oscillating in several dimensions relative to the frame subregion by means of at least one connecting element connecting the mirror subregion and the frame subregion and which can be designed in particular as a connecting web or mechanical spring.

The present invention relates to a glass substrate-based MEMS mirror device and a method for its production.

MEMS mirror devices, which are also referred to as “microscanners”, “MEMS scanners”, “MEMS mirrors” or “micromirrors”, are basically micromechanical systems for deflecting electromagnetic radiation, which can be used, for example, to solve imaging sensory tasks or to implement display functionalities. In addition, such MEMS mirror devices can also be used to irradiate materials in an advantageous manner and thus also to process them. Possible other applications are in the field of illumination or lighting of certain open or closed spaces or space areas with electromagnetic radiation, for example in the context of spotlight applications.

MEMS mirror devices can be used in particular to deflect electromagnetic radiation in order to modulate, by means of a deflection element (“mirror”), an electromagnetic beam incident thereon with respect to its deflection direction. This can be used in particular to cause a Lissajous projection of the beam into an observation field. For example, imaging sensory tasks can be solved or display functionalities can be realized. In addition, such MEMS mirror devices can also be used to irradiate materials in an advantageous manner and thus also to process them. Possible other applications are in the field of illumination or lighting of certain open or closed spaces or space areas with electromagnetic radiation, for example in the context of spotlight applications.

As usual, the acronym “MEMS” here stands for the term “micro-electro-mechanical system” or “microsystem” for short. This regularly refers to a miniaturized device, assembly or component whose components have the smallest dimensions in the range of 1 micrometer or less and interact as a system.

From U.S. Pat. No. 8,711,456 B2 a MEMS mirror device based on a silicon wafer is known, which together with a corresponding control forms a deflection device for a scanner with Lissajous scanning. It contains a micromirror which oscillates about at least two deflection axes and which has a frame and a mirror plate arranged movably via a suspension. By means of the controller, the mirror can be made to oscillate resonantly in two dimensions so that when the mirror is illuminated with an electromagnetic beam, an overall Lissajous scan can be generated.

Fabrication of MEMS scanners with larger apertures (e.g., with mirror plate diameters>5 mm) results in a significant cost increase in manufacturing if MEMS silicon technologies known from the prior art are used for this purpose. Silicon-based fabrication of MEMS devices is particularly cost-effective when a very large number of devices can be accommodated on one silicon wafer. If the square or rectangular chips are of small dimensions, then the chips can be placed on the wafer layout well enough to approximate the edge of the circular silicon disk (wafer) and produce little waste material. However, if the individual chips become quite large relative to the wafer diameter, as can be the case in MEMS scanners due to a large mirror diameter to be realized, then the surface of lost, unusable surface areas on the wafer increases disproportionately. The yield of good chips is then very low simply because of the poor approximation of the wafer format due to the arrangement of the individual large chips on the wafer.

Since in silicon technology a large part of the manufacturing equipment consists of complex highly specialized expensive vacuum equipment, which provides for slow loading and unloading and which must also be subject to constant maintenance and servicing, the result is a relatively very expensive manufacturing process with relatively low throughput, which suffers from a lack of economic efficiency with a small number of components per wafer as well as too large unusable waste areas on the wafer.

It is therefore the object of the present invention to provide a MEMS mirror device which is further improved in comparison and an improved method for its production.

A solution to this object is achieved according to the teachings of the independent claims. Various embodiments and developments of the invention are the subject of the development claims.

A first aspect of the invention relates to a MEMS mirror device for variably deflecting an incident electromagnetic beam, in particular a light beam having at least one component in the visible range or in the infrared range of the electromagnetic spectrum. The electromagnetic beam may in particular be a laser beam. The MEMS mirror device has a disk-shaped first glass substrate structured into a plurality of subregions with a mirror subregion formed at least partially as a MEMS mirror for reflecting electromagnetic radiation and a frame subregion surrounding the mirror subregion at least in sections. The mirror subregion is designed as a subregion of the first glass substrate suspended so as to be capable of oscillating in several dimensions relative to the frame subregion by means of at least one connecting element connecting the mirror subregion and the frame subregion and which can be designed in particular as a connecting web.

The disk-shaped glass substrate can thus correspond in particular to a glass plate structured at least in the said subregions, wherein the mirror subregion and optionally also one or more other subregions of the glass substrate can be coated or equipped with a material, in particular a metallic material.

For the purposes of the invention, a “MEMS mirror” means a part or component of a MEMS mirror device that has a surface reflecting electromagnetic radiation that is smooth enough for the reflected electromagnetic radiation to retain at least most of its parallelism according to the law of reflection and thus to form an image. The roughness of the mirror surface must be less than about half the wavelength of the radiation for this to occur. In particular, the diameter of such a MEMS mirror can be 30 mm or less. However, MEMS mirrors with larger diameters that can be manufactured as part of a MEMS fabrication process are conceivable.

The terms “comprises,” “includes,” “contains,” “features,” “has,” “with,” or any other variation thereof as used herein are intended to cover a non-exclusive inclusion. For example, a method or device that includes or has a list of elements is not necessarily limited to those elements, but may include other elements not specifically listed or inherent in such method or device.

Further, unless expressly stated to the contrary, “or” refers to an inclusive or and not an exclusive “or”. For example, a condition A or B is satisfied by one of the following: A is true (or present) and B is false (or absent), A is false (or absent) and B is true (or present), and both A and B are true (or present).

The terms “a” or “one” as used herein are defined in the sense of “a/one or more”. The terms “another” and “a further”, and any other variant thereof, are to be understood in the sense of “at least one more”.

The term “plural” as used herein shall be understood in the sense of “two or more”.

The processing of glass substrates using suitable glass patterning methods enables cost-effective production, especially of large-area MEMS scanners. This is due to several reasons, in particular the following: (1) glass substrates can be fabricated very inexpensively in many different formats and thicknesses; (2) glass substrates can be much larger than silicon wafers and thus can accommodate many more chips. For example, glass can be fabricated and patterned in rectangular plates instead of round wafers. This eliminates the many waste regions on a wafer that occur when circular wafers are used when they are approximated by rectangular chips; (3) the preferred methods for patterning glass substrates are usually either laser-based, abrasive, or wet chemical and do not require expensive vacuum equipment technology. On the one hand, this means that complex photolithographic processes can be dispensed with and, on the other hand, the intermediate products or end products can be fed in and out of the individual systems of a corresponding production line much more easily and quickly, and thus also more cost-effectively, than with conventional silicon technology. Thus, a significantly increased throughput, a correspondingly shorter overall process time, and thus also a significantly increased economic efficiency can be achieved.

A MEMS mirror device according to the aforementioned first aspect of the invention can thus deliver the aforementioned advantages with respect to its manufacture. In addition, based in particular on the preferred embodiments of the MEMS mirror device described below, further advantages, including functional advantages, can be achieved. These embodiments can in each case, insofar as this is not expressly excluded or would be technically impossible, in particular contradictory, be arbitrarily combined with each other as well as with the method aspect of the invention described further below.

In some embodiments, the MEMS mirror device further comprises a second glass substrate that is directly or indirectly connected to the first glass substrate (e.g., via a bonding material or one or more intermediate substrates) in such a way that, together therewith, it forms a cavity surrounding the mirror subregion on at least one side of the first glass substrate, into which immersed the mirror subregion can execute an oscillatory motion, in particular a multidimensional one. With the aid of such a structure, it is possible to achieve that in particular the mirror subregion and its oscillatory motion are physically protected by the second glass substrate.

A “multidimensional oscillatory motion” in the sense of the invention is to be understood as a motion of an object, here in particular of the mirror subregion of the MEMS mirror device, in which the object executes an oscillatory motion, i.e. a motion in which repeated temporal fluctuations of the spatial position of the object occur, with respect to at least two different degrees of freedom. In particular, the oscillatory motion can be resonant, i.e. correspond to a corresponding natural oscillation of the oscillatory system with respect to at least one of the degrees of freedom, in this case specifically the oscillatory motion of the mirror subregion relative to the frame subregion.

According to a first variant, the second glass substrate can be formed in particular as a lid for closing off the cavity at least on one side. In particular, the second glass substrate can be shaped in such a way that an angle at which the incident radiation directed onto the MEMS mirror is partially reflected when it strikes the lid is a different angle than the angle at which the part of the radiation that reaches the MEMS mirror and is reflected there emerges again through the lid. Thus, interfering reflections in the image emanating from the reflection at the lid can be avoided. In particular, the lid can have a dome shape, at least in sections, for this purpose. The dome shape can thus form a boundary wall of the cavity. In this context, it is preferably arranged in such a way that, during operation of the MEMS mirror device, the electromagnetic radiation to be deflected by the MEMS mirror falls through the dome shape onto the MEMS mirror and/or the radiation reflected at the MEMS mirror leaves the MEMS mirror device again through the dome shape. DE 10 2017 213070 A1 describes an exemplary embodiment of such a second glass substrate, but in combination with a silicon wafer. The dome shape can in particular have a circular arc-shaped or elliptical arc-shaped cross-section, although other shapes which are at least partially arc-shaped, in particular those with only one vertex, are also possible as dome shapes. Instead of a dome shape, however, other cover shapes are also possible in which the disturbing reflections in the image can be avoided. In particular, the cover can have a planar surface for this purpose, which is intended to receive the incident radiation and allow it to pass through at least partially, wherein this surface is angled with respect to the mirror surface of the MEMS mirror so that the desired different reflection angles result. In cross-section, the contour of such a cover may in particular have a triangular shape.

Alternatively, the second glass substrate can be designed as a planar cover substrate, which is indirectly connected to the first glass substrate via a spacer substrate. Such planar constructions are particularly suitable for applications in which the irradiated electromagnetic radiation can be separated from the radiation reflected by the cover substrate itself and from the radiation deflected by the MEMS mirror by means of a different configuration, for example by one or more apertures or by spatially variable refractive indices in the substrate material of the second glass substrate. Compared to the aforementioned cover shapes, in particular also compared to a dome-shaped cover or substrate, they usually offer the advantage of a simpler and thus less complex manufacturability of the second glass substrate.

In some embodiments, the MEMS mirror device further comprises a third substrate that is directly or indirectly connected to the first glass substrate on its side opposite the second glass substrate such that, together with the second glass substrate, it forms the cavity such that it surrounds the mirror subregion on both sides such that the mirror subregion can perform the oscillatory motion in the cavity. In particular, the third substrate may itself also be a glass substrate. Instead, it may also be formed of one or more other materials, such as silicon in particular. In particular, the third substrate can form a bottom substrate of the MEMS mirror device and close off the bottom of the cavity formed on both sides of the first glass substrate. The mirror subregion can thus be immersed in the cavity on both sides of the first glass substrate forming it during its oscillatory motion, wherein it is physically protected and, depending on the filling of the cavity, also chemically protected by the boundary walls of the cavity, which are formed in particular by the second glass substrate and the third substrate.

In some embodiments, the cavity is formed as a gas-tight cavity in which a lower gas pressure, in particular a vacuum, prevails compared to normal conditions, i.e. 101.325 kPa (1013.25 mbar). In particular, this can be implemented by means of a hermetic vacuum encapsulation within the substrate stack itself, which is formed in particular by the first, second and third substrates, or by means of a separate housing (second-level package) enclosing the substrate stack.

The term “vacuum” is used here to describe the state of a gas when the pressure of the gas, and thus the particle number density, is lower in a container (here: the encapsulation defining the cavity) than outside, or when the pressure of the gas is lower than 300 mbar, i.e. lower than the lowest atmospheric pressure occurring on the earth's surface.

In these embodiments, any energetic losses due to friction occurring during the oscillatory motion of the mirror subregion can be reduced, in particular minimized or even essentially avoided. Due to the reduced gas pressure or vacuum, the oscillatory motion of the mirror subregion is damped by the residual gas at most slightly and almost not at all, and thus maximum oscillation amplitudes can be achieved. Furthermore, in addition to physical protection, this also results in chemical protection of the components located in the cavity, in particular the MEMS mirror. Especially in non-resonant or quasi-static mode, the vacuum encapsulation of the cavity can be replaced by an inert gas filling of the hermetically sealed cavity. This allows oscillation characteristics, such as damping behavior, to be specifically adjusted. In this way, stable operation can be made possible for certain operating modes, including quasi-static operation.

In some cavity embodiments, the MEMS mirror device further comprises at least one residual gas getter element comprising a chemically reactive material disposed in the cavity and configured to chemically bind any gas particles present in the cavity to the residual gas getter element. In this way, any remaining residual gas can be reduced, further increasing the quality of the vacuum. Thus, on the one hand, the frictional damping influencing the oscillatory motion can be further reduced and, on the other hand, the chemical protection of the components, in particular the mirror subregion, can also be strengthened. In some of these embodiments, the residual gas getter element can also serve as an electrode, in particular a bottom electrode, for a capacitive position determination device for determining a deflection position of the mirror subregion. This serves to simplify the setup and the required material and productionacturing expenses.

In some embodiments, the MEMS mirror device further comprises one or more fourth substrates that collectively form a spacer layer through which the respective indirect connection of the second glass substrate or the third substrate to the first glass substrate is made. The fourth substrate or substrates may be formed, in particular, of a glass material or of a semiconductor material, such as silicon. The or each of the fourth substrate(s) may in particular perform the function of a distance keeper or “spacer” by being disposed between the first glass substrate and a bottom substrate, in particular the third substrate, and having a cavity defining, at least in part, a portion of the cavity located between the first glass substrate and the bottom substrate. The mirror subregion can thus be immersed in the cavity on both sides of the first glass substrate forming it during its oscillatory motion, wherein it is physically and ideally also chemically protected by the boundary walls of the cavity, which are partially formed by the inner wall of the cavity of the fourth substrate or substrates.

In some embodiments, the mirror subregion is formed as a double-sided MEMS mirror. On the one hand, this makes it possible to extend the scanning area or projection area to both sides of the MEMS mirror device or the first glass substrate, if the second mirror side is also used for scanning or projection. On the other hand, however, this also provides a further possibility for determining the position with respect to the mirror subregion by directing an electromagnetic measuring beam onto one of the two mirror surfaces and using its deflection at the mirror, in particular the deflection angle occurring in space, as a measure of the position of the mirror subregion.

In some embodiments, the third substrate has a dome shape at least in sections and the mirror subregion is formed as a MEMS mirror on both sides. In particular, the cavity may thus have a dome-shaped boundary wall on each side of the mirror subregion. The combination of these features allows the mirror subregion to be used on both sides as a deflection mirror for electromagnetic radiation and thus to extend the illuminable scanning or projection area to both sides of the first glass substrate, in particular up to a scanning or projection angle per axis of oscillation of almost 360°, per axis (i.e. only excluding the respective angular areas covered by the first glass substrate).

In some embodiments, the first glass substrate or, optionally, one of the further glass substrates is made of a silicate-based glass material, a quartz glass, or a glass material containing two or more such glass materials. Particularly suitable examples of such glass materials are, in particular, the following types of glass: SCHOTT Borofloat 33, CORNING EAGLE XG, CORNING PYREX 7740, SCHOTT AF32, SCHOTT BK7 or CORNING Quarzglas HPFS, Hereaus Conamic HSQ 900. These glass materials have in common that they are silicate-based and have high transmission in the electromagnetic wavelength range from 350 nm to 2500 nm, which makes them particularly suitable as a material for the production of a MEMS mirror device according to the invention. A quartz glass is particularly preferable when the electromagnetic radiation has a relatively high intensity, as may be the case when lasers with high laser power are used, e.g. above 200 W. Ideally, in such a case, all substrates of the MEMS mirror device are made of the same quartz glass in order to achieve an optimal thermal match between the glass substrates.

In some embodiments, the MEMS mirror device further comprises a position determination device for determining a current deflection position of the mirror subregion, in particular relative to the frame subregion. This is particularly advantageous if the MEMS mirror device is driven or operated in such a way that knowledge of the current deflection position, in particular the current orientation, of the mirror subregion is required at certain times or continuously during operation. This may be the case, for example, if the MEMS mirror device is used as a projection device and the image content to be projected, which may be reflected in particular in a current intensity or coloring of the electromagnetic radiation used, must be controlled as a function of the current deflection position. The same applies in the opposite direction when scanning a field of view, in particular if the scanning is not performed in a grid-like manner, as is the case, for example, when the multidimensional oscillatory motion is performed in the form of a Lissajous oscillatory motion.

In some embodiments, the position determination device is configured to use at least one of the following measurement principles to determine the position of the mirror subregion: (i) magnetic induction due to a magnetic interaction between a permanent magnet and a magnetic field sensor, in particular a detection coil, wherein the permanent magnet is arranged on or in the mirror subregion, and the magnetic field sensor is arranged separately from the mirror subregion, or vice versa; (ii) generation of an electrical measurement voltage at a piezoelectric element mechanically coupled to the mirror subregion or its suspension; (iii) optical position determination by means of an optical transmitter which transmits electromagnetic radiation onto the mirror subregion, in particular its side opposite the MEMS mirror, and an optical receiver which measures the radiation thereby reflected by the mirror subregion; (iv) electrical capacitance measurement between two electrodes arranged on the MEMS mirror device such that the electrical capacitance measurable between the two electrodes depends on the current deflection position of the mirror subregion. (v) Use of at least one strain gauge (e.g. piezoresistive type) to measure a state, in particular a strain, of at least one connecting element.

When using the magnetic interaction according to variant (i), particularly good signal-to-noise ratios (SNR) can be achieved for position determination. In addition, a separate drive of the mirror subregion, in particular by means of a piezoelectric actuator, can also be dispensed with here (cost saving), for example if a force effect can be exerted on the permanent magnet by temporarily using the detection coil as an excitation coil via the known Lorenz force. Variant (ii), on the other hand, allows particularly small form factors for the position determination device and that the piezoelectric element can be used alternately for position determination and for driving the mirror subregion. In addition, it is possible to use multiple piezoelectric elements, wherein one part of the elements is used for position determination and another part for driving. With the optical measurement according to variant (iii), a particularly high accuracy for the position determination can be realized. The capacitive measurement according to variant (iv) is in particular simple and can be realized in a wide variety of configurations of the electrodes. This also enables, in particular, an accurate and contact-free real-time measurement of the deflection position.

In variant (iv), at least one of the electrodes may be formed in particular in one of the following ways: (iv-1) as a metallic coating on or in the mirror subregion, which at least in sections simultaneously forms the MEMS mirror for reflecting electromagnetic radiation; (iv-2) as a metallic coating on or in the mirror subregion, which is formed separately from the mirror surface forming the MEMS mirror; (iv-3) as a metallic coating on or in the frame subregion of the first glass substrate; (iv-4) as at least one electrode element formed on one side of the third substrate; (vi-5) as an electrode structured into a plurality of separate electrode elements, wherein at least two of the separate electrode elements are differentially connected to each other.

Variant (iv-1) has the particular advantage that a metallic coating which is already present anyway can be used at the same time for position determination in the sense of “dual-use”. Variants (iv-2) and (iv-4) can be used particularly well in combination in order to carry out the position determination by means of capacitance measurement in the space area extending between the mirror subregion and the third substrate (which can in particular form a bottom substrate of the MEMS mirror device), in particular cavity region, with high accuracy and independently of the geometry of the layer forming the MEMS mirror. For this purpose, the metallic coating is preferably arranged on a bottom side of the mirror subregion opposite to the MEMS mirror. Variant (iv-3) is particularly suitable for providing a lateral capacitor for capacitance measurement on or in the first glass substrate, wherein the counter electrode can be fabricated as part of the same layer as the mirror layer or mirror electrode. This, in turn, can reduce production complexity and production effort. In variant (iv-4), the electrode (bottom electrode) can be either in electrically contacted form or as an electrically free-floating (“floating”) electrode. The latter has the advantage that the production effort associated with the production of such a contact, in particular with the production of vias and associated contact pads, can be saved. Variant (iv-5) in particular enables capacitance measurements with a high signal-to-noise ratio (SNR) and thus with particularly high robustness and accuracy.

Variant (v) also makes it possible to consider its suspension (e.g. connecting webs) instead of the mirror subregion itself in order to determine its position, since their position, in particular elongation, corresponds to the position of the mirror subregion.

In some embodiments, the respective glass materials of at least two interconnected glass substrates, preferably all of the glass substrates present, have the same thermal expansion coefficient or a thermal expansion coefficient that does not differ by more than 10⁻⁴ K⁻¹. Thus, thermal stresses can be largely avoided, which in particular promotes the mechanical stability and reliable operation of the MEMS mirror array.

In some embodiments, the MEMS mirror device further has a drive device that is set up to set the mirror subregion into a multidimensional, in particular resonant, oscillatory motion relative to the frame subregion. In this way, the MEMS mirror device becomes an active component that itself has a drive for the mirror motion and can independently perform the desired scanning function when appropriately controlled.

In some of these embodiments, the mirror subregion is suspended so as to be capable of oscillating relative to the frame subregion in such a way that, when suitably excited by means of the drive device, it performs the multidimensional oscillatory motion in the form of a Lissajous oscillatory motion, in particular a resonant Lissajous oscillatory motion. Thus, the advantages of Lissajous scanning over conventional raster scanning can also be used in the glass substrate-based MEMS mirror device according to the invention. In particular, the drive device may include one or more piezoelectric actuators for exciting the oscillatory motion of the mirror subregion.

In some embodiments, the drive device particularly comprises a piezoelectric actuator that is indirectly mechanically coupled to the first glass substrate via at least one of the other one or more glass substrates. According to a first variant, the piezoelectric actuator(s) can thereby “shake” the mirror device, in particular as part of a oscillating motion generated by it, in such a way that the oscillation energy is transmitted to the mirror subregion and excites it to oscillate, in particular to oscillate resonantly or forcedly. In the case of a mirror subregion capable of oscillating two-dimensionally, in particular about two orthogonal axes, the drive device or a control for it can be configured in particular in such a way that the excitation of the oscillation of the mirror subregion takes place by means of an excitation signal which contains the resonance frequencies with respect to the two oscillation dimensions, preferably as dominant frequency components of the excitation signal.

According to a second variant for this purpose, which can be provided instead of or cumulatively with one of the first variants, the drive device has one or more piezoelectric elements on the connecting elements in order to set the mirror subregion in an oscillating motion relative to the frame subregion by activating the piezoelectric elements. In this way, the energy supply from the drive device to the mirror subregion can take place over a particularly short distance and with particularly low damping. In addition, individual oscillation axes of the oscillation of the mirror subregion can be excited particularly well individually and with at least extensive avoidance of couplings between the axes.

In some embodiments, the mirror subregion has a metallic coating, in particular in the form of a coating, which is formed at least in sections as a mirror surface for deflecting the electromagnetic beam. In this regard, the metallic layer includes one or more of the following metallic materials: aluminium (Al), gold (Au), silver (Ag). All these materials have in common that on the one hand they form very durable layers and on the other hand they can also provide very good mirror properties. This makes these materials particularly suitable as materials for the aforementioned layer or coating on the first glass substrate.

In some embodiments, at least one side of the first glass substrate, in particular a side having a mirror surface for deflecting irradiated electromagnetic radiation, is metallically coated over its entire surface. Thus, during production, a process for patterning this metallic coating may be omitted, which may help to reduce production complexity and effort, production time, and thus associated production costs.

In some embodiments, the MEMS mirror device further comprises a separate package (so-called “second-level package”) for housing the connected substrates (substrate stacks) of the MEMS mirror device. Among other things, this allows for good integrability into higher-level systems, particularly if the separate package is configured with solder joints (e.g., solder balls) or other connection elements for connection to a system component, such as a system circuit board.

In some embodiments, the mirror subregion or the frame subregion is thickened in thickness by connecting (bonding) to at least one further substrate (“reinforcing substrate”). The first glass substrate and the reinforcing substrate can in particular have different thicknesses, which can be used in particular to build springs (e.g. connecting webs) and mirror subregions of different thicknesses from them, depending on the design and application. In this way, in particular, the number of excitable degrees of freedom for the oscillating motion of the mirror subregion can be increased and the mirror subregion or frame subregion can be mechanically stiffened. These respective reinforcements of the mirror subregion or the frame subregion individually and in particular also cumulatively provide the advantage that a lower deformation of the mirror subregion (if it is thickened) or the frame subregion (if it is thickened) occurs when the mirror subregion oscillates. Thus, the damping of the oscillation as well as at least a better mechanical decoupling of the different oscillation axes (by reduction of a possible coupling of the oscillation axes via the frame partial area) can be achieved.

A second aspect of the invention relates to a method of production a MEMS mirror device, the method comprising: (i) simultaneously forming a plurality of similar MEMS mirror devices according to the first aspect of the invention using at least one disc-shaped glass substrate common to all of said MEMS mirror devices, which may in particular be the respective first glass substrate of said MEMS mirror devices; and (ii) separating said MEMS mirror devices after simultaneous formation thereof.

Some preferred embodiments of the method are described below. These embodiments can in each case be combined with one another as desired, unless this is expressly excluded or would be technically impossible, in particular contradictory.

In some embodiments, a glass substrate is used as the common disc-shaped glass substrate, which has a rectangular disc-shape before separation. In this way, a better approximation or area utilization and thus a higher area yield for a given gross substrate area can be achieved compared to round wafers while reducing or even avoiding unused loss areas on the glass substrate.

Preferably, the common disc-shaped glass substrate used is a glass substrate having an area of at least 100 cm², preferably 1000 cm² or more.

In some embodiments, the respective first glass substrate of the individual MEMS mirror devices emerges from the common glass substrate by structuring it using at least one glass structuring process. In this way, in particular the mirror subregion and the frame subregion as well as the at least one connecting element, in particular connecting web, can be formed integrally from a single substrate.

In some embodiments, the structuring of the common glass substrate or at least one other of the substrates respectively present in the MEMS mirror devices is performed using a laser-based etching method. In this way, particularly short process times and particularly precise patterning can be achieved. In some of these embodiments, the patterning of the common glass substrate or at least another of the substrates present in each of the MEMS mirror devices is performed using a laser-induced chemical etching process, which may in particular be a so-called laser induced deep etching, LIDE etching, etching method. In such a LIDE etching method, a pulsed high-energy laser is used to damage and structurally alter the glass in the exposed areas so that it can be selectively removed in a subsequent wet chemical etching process.

The features and advantages explained with respect to the first aspect of the invention apply accordingly to the method aspect of the invention, and in particular to the resulting products.

Further advantages, features and possible applications of the present invention will be apparent from the following detailed description in connection with the figures.

Showing:

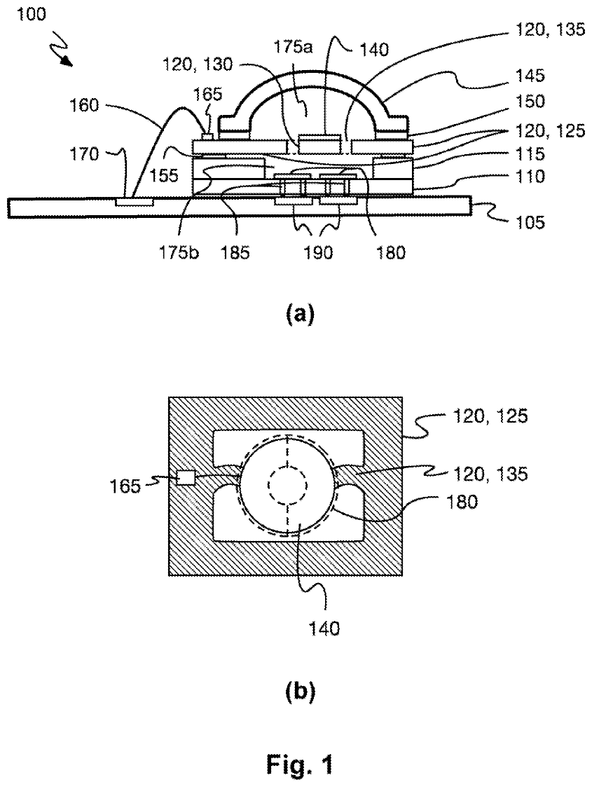

FIG. 1 schematically shows a first exemplary embodiment of a MEMS mirror device according to the invention, including electrodes for capacitive position determination and a piezoelectric actuator as a drive device;

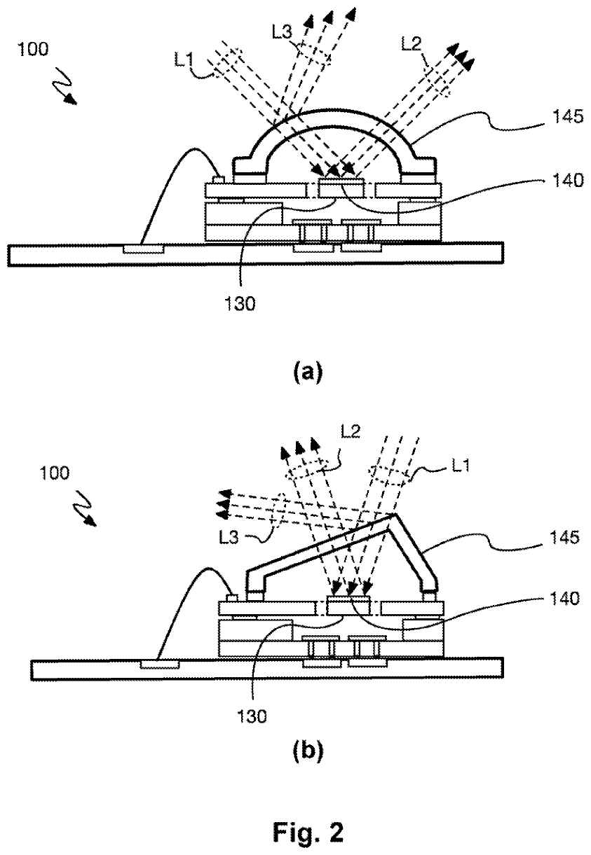

FIG. 2 schematically shows the radiation path in an encapsulation of the MEMS mirror device, in particular in the embodiment according to FIG. 1, by means of a dome-shaped encapsulation or an encapsulation that is angled relative to the rest position of the mirror subregion, in particular a saddle-roof-shaped encapsulation;

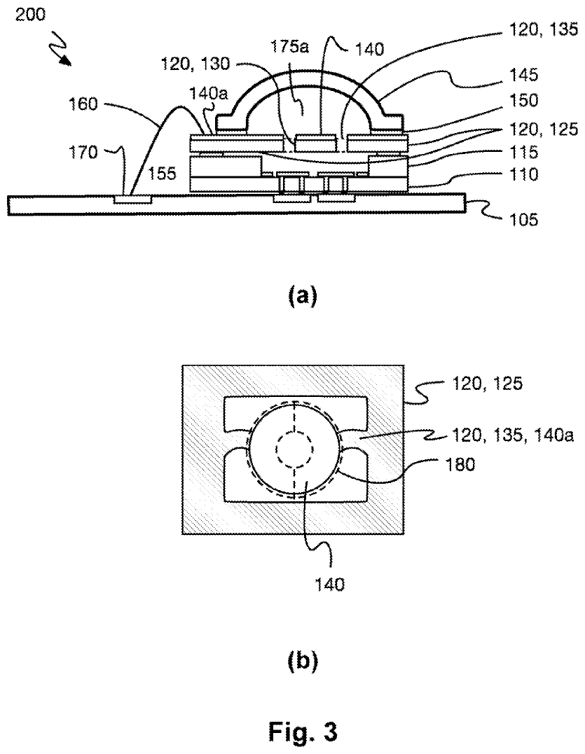

FIG. 3 schematically illustrates a second exemplary embodiment of a MEMS mirror device according to the invention, in which one side of the first glass substrate is coated with metal over its entire surface;

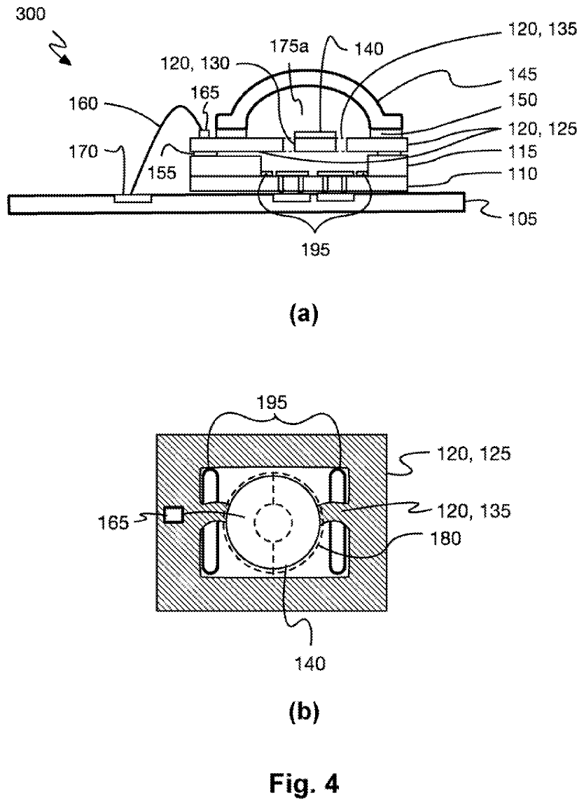

FIG. 4 schematically illustrates a third exemplary embodiment of a MEMS mirror device according to the invention, in which residual gas getter elements are provided to improve the vacuum in the cavity around the miniature mirror;

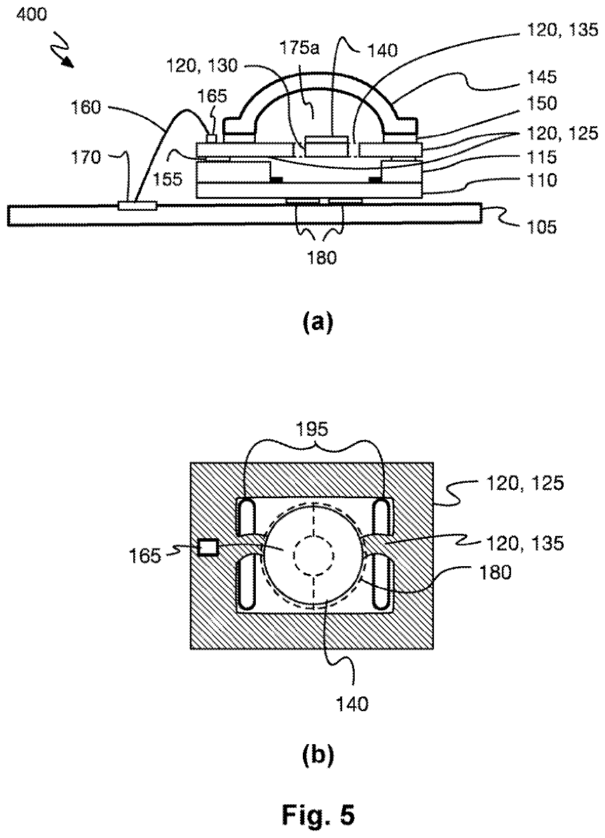

FIG. 5 schematically illustrates a fourth exemplary embodiment of a MEMS mirror device according to the invention, in which a bottom electrode of a position determination device is arranged on the outside of the bottom substrate and thus outside the cavity;

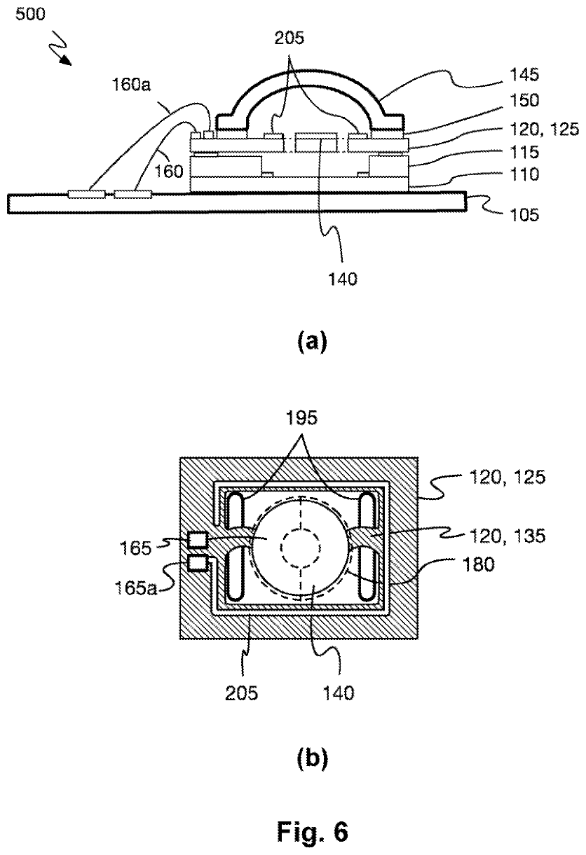

FIG. 6 schematically illustrates a fifth exemplary embodiment of a MEMS mirror device according to the invention, in which the electrodes of a position determination device are formed as different sections of a same metallization layer on the first glass substrate;

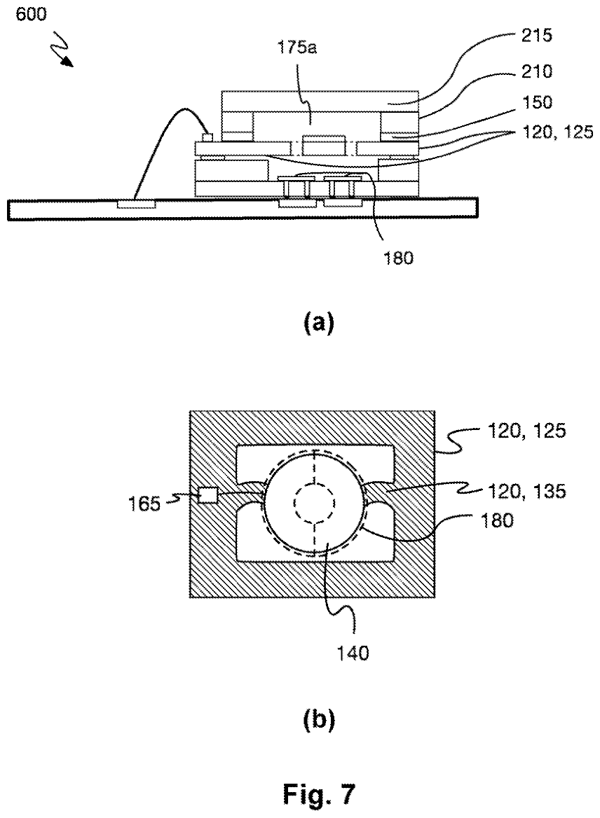

FIG. 7 schematically illustrates a sixth exemplary embodiment of a MEMS mirror device according to the invention, in which a planar cover substrate, which is indirectly connected to the first glass substrate via a spacer substrate, is provided;

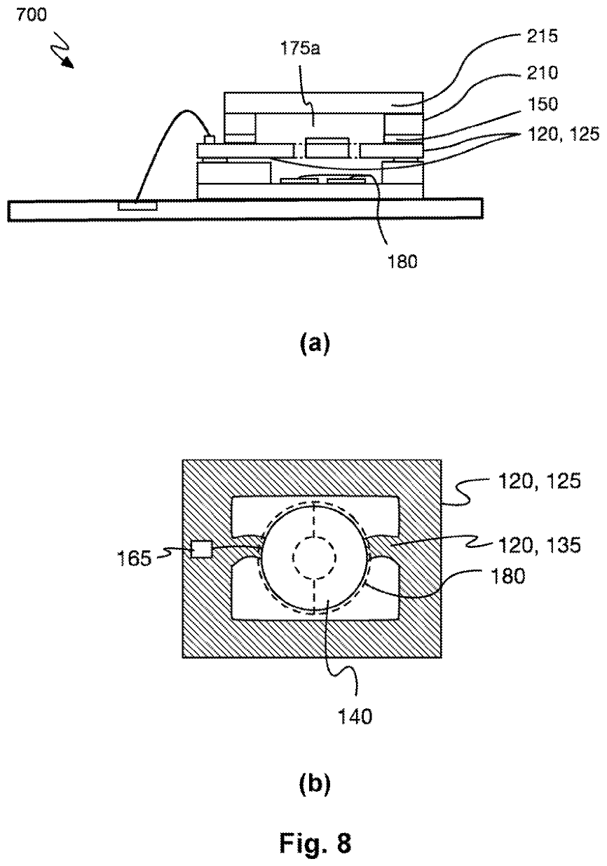

FIG. 8 schematically shows a seventh exemplary embodiment of a MEMS mirror device according to the invention, in which a bottom electrode of a position determination device is designed as an electrically “floating” electrode;

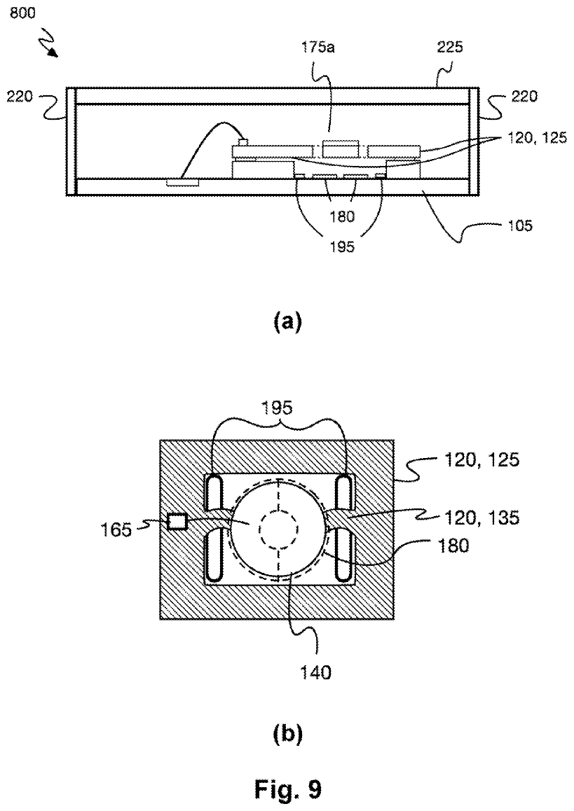

FIG. 9 schematically shows an eighth exemplary embodiment of a MEMS mirror device according to the invention, in which the multilayer stacked structure is encased by means of a separate housing (second-level package);

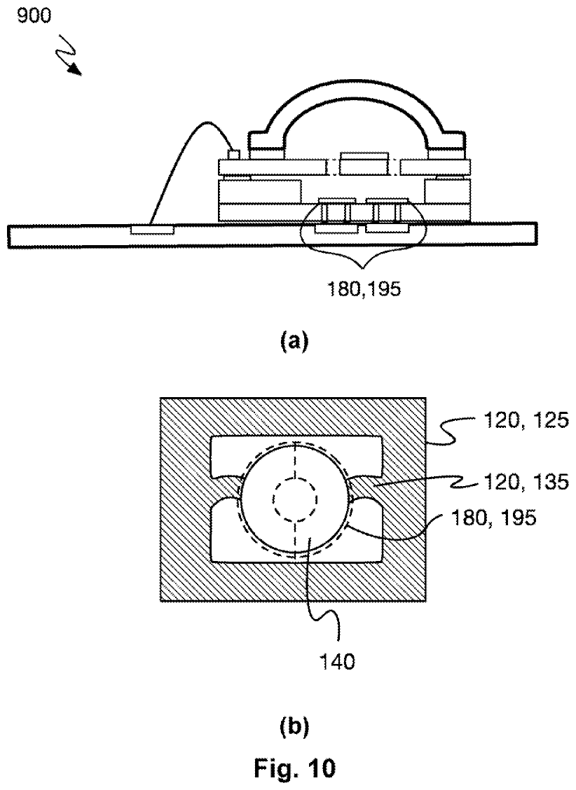

FIG. 10 schematically illustrates a ninth exemplary embodiment of a MEMS mirror device according to the invention, in which the bottom electrode and the residual gas getter elements coincide;

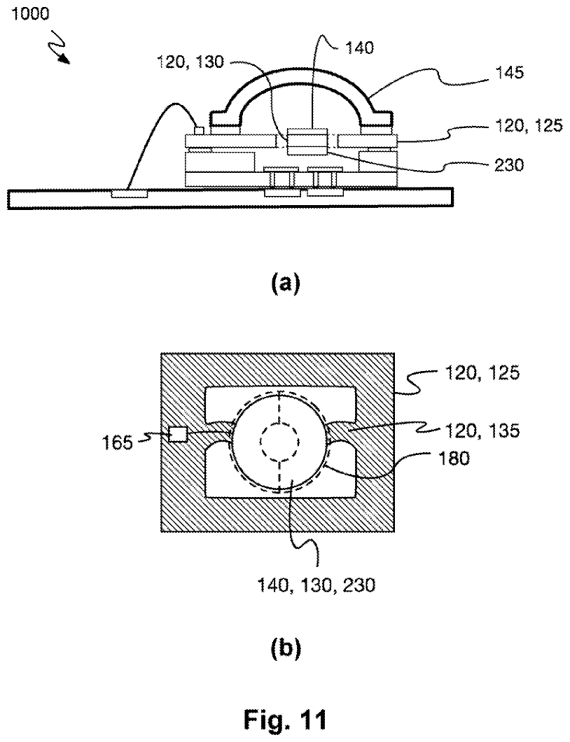

FIG. 11 schematically illustrates a tenth exemplary embodiment of a MEMS mirror device according to the invention, in which the mirror subregion is thickened in its thickness by connecting (bonding) with at least one reinforcing substrate;

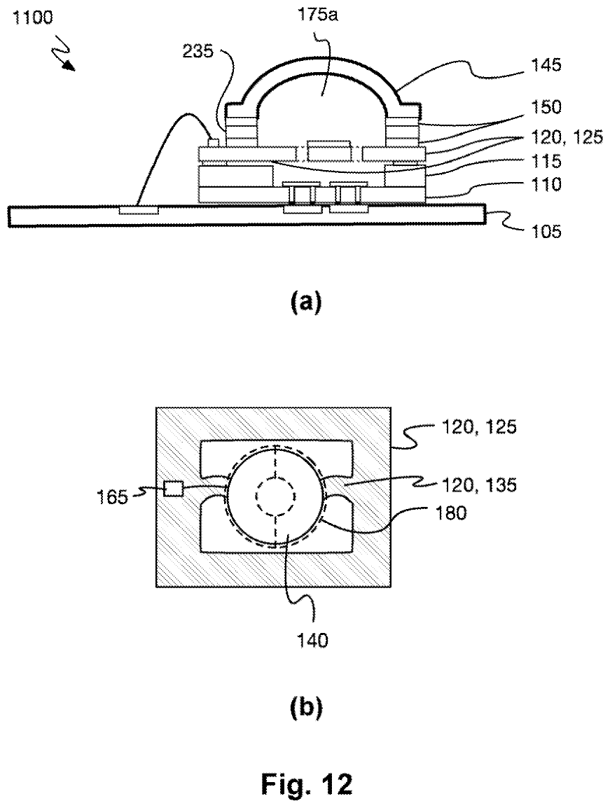

FIG. 12 schematically shows an eleventh exemplary embodiment of a MEMS mirror device according to the invention, in which all glass substrates of the MEMS mirror device are made of a quartz glass material and a further spacer substrate is provided below the second glass substrate;

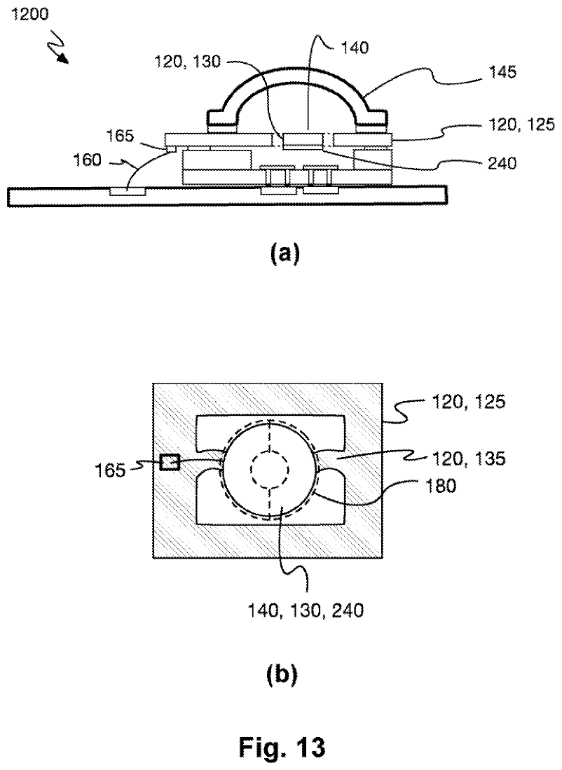

FIG. 13 schematically illustrates a twelfth exemplary embodiment of a MEMS mirror device according to the invention, in which the bottom-side rear of the mirror subregion is coated with a layer that is a good electrical conductor and forms a counter electrode (top electrode) to the bottom electrode;

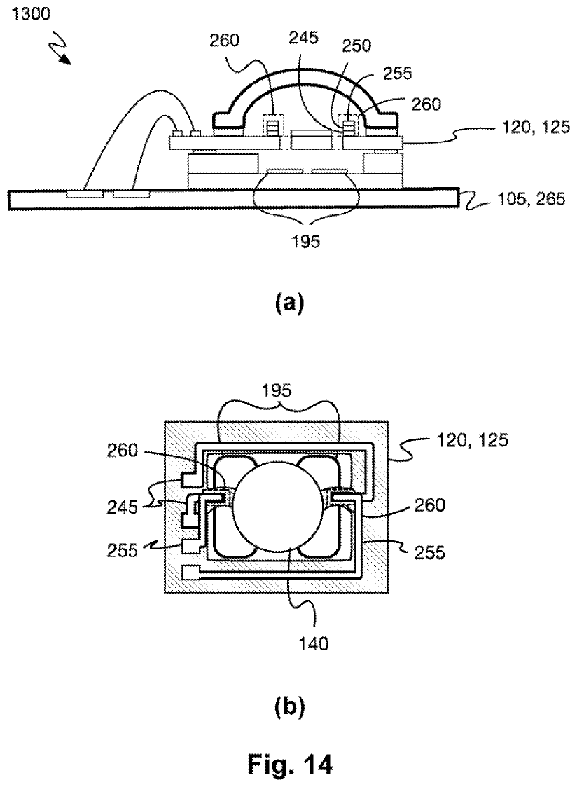

FIG. 14 schematically illustrates a thirteenth exemplary embodiment of a MEMS mirror device according to the invention, in which a piezoelectric element is provided for determining the position and/or for driving the mirror subregion;

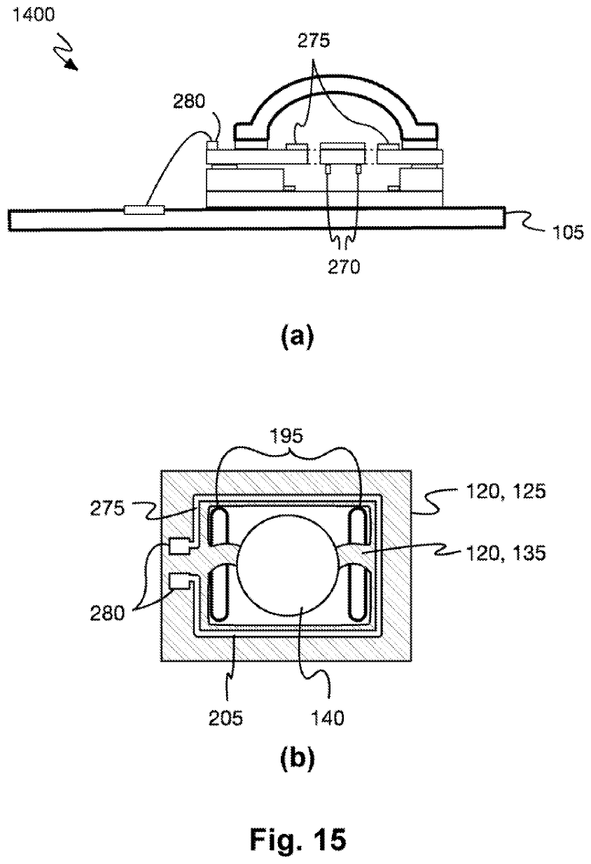

FIG. 15 schematically shows a fourteenth exemplary embodiment of a MEMS mirror device according to the invention, in which a magnetic arrangement with at least one permanent magnet and a detection coil is provided for determining the position and/or for driving the mirror subregion;

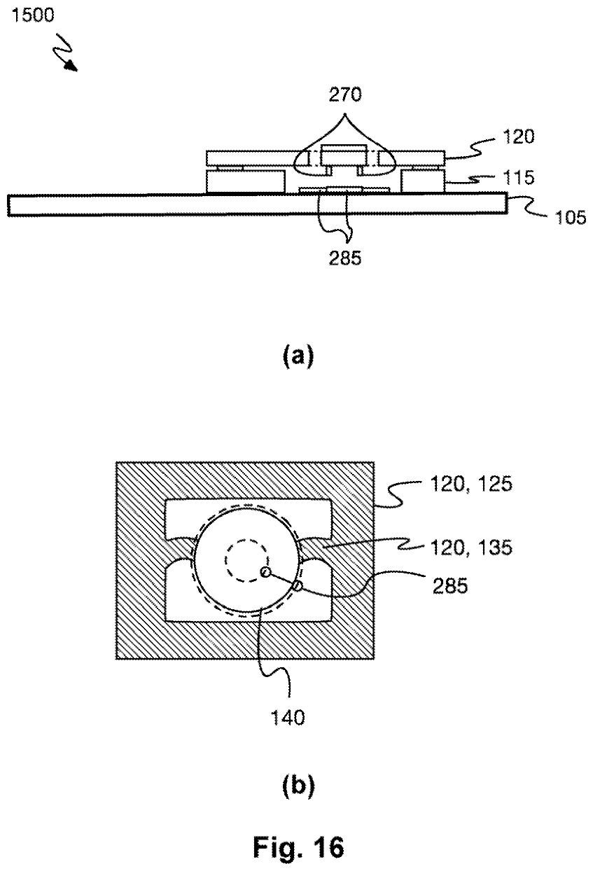

FIG. 16 schematically illustrates a fifteenth exemplary embodiment of a MEMS mirror device according to the invention in which hermetic encapsulation is omitted;

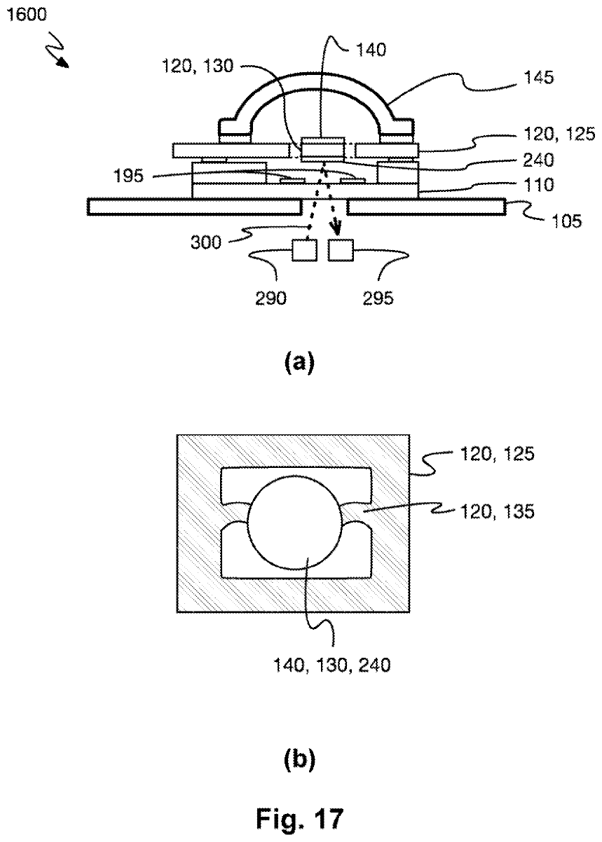

FIG. 17 schematically illustrates a sixteenth exemplary embodiment of a MEMS mirror device according to the invention, in which an optical position determination device is provided;

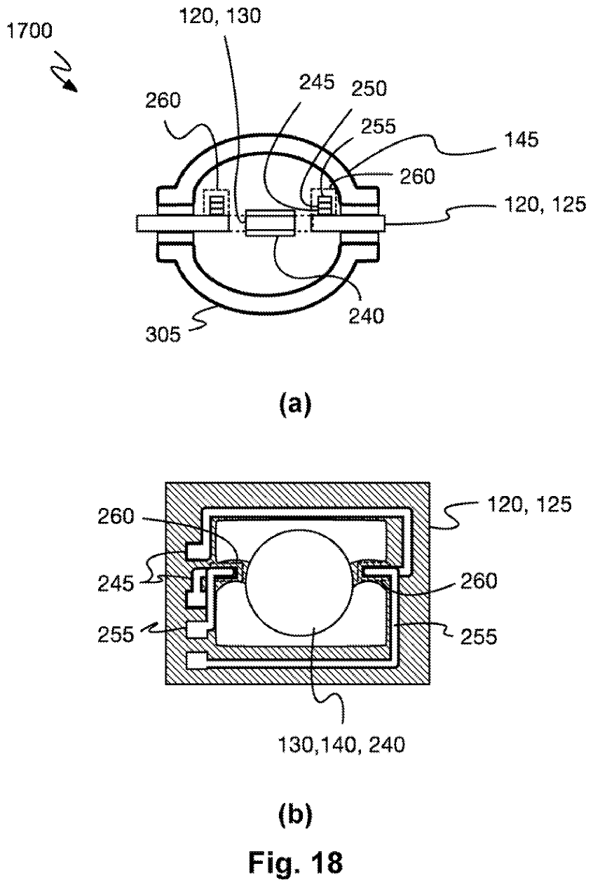

FIG. 18 schematically illustrates a seventeenth exemplary embodiment of a MEMS mirror device according to the invention, in which the first glass substrate is encapsulated on both sides in each case by a dome-shaped glass substrate;

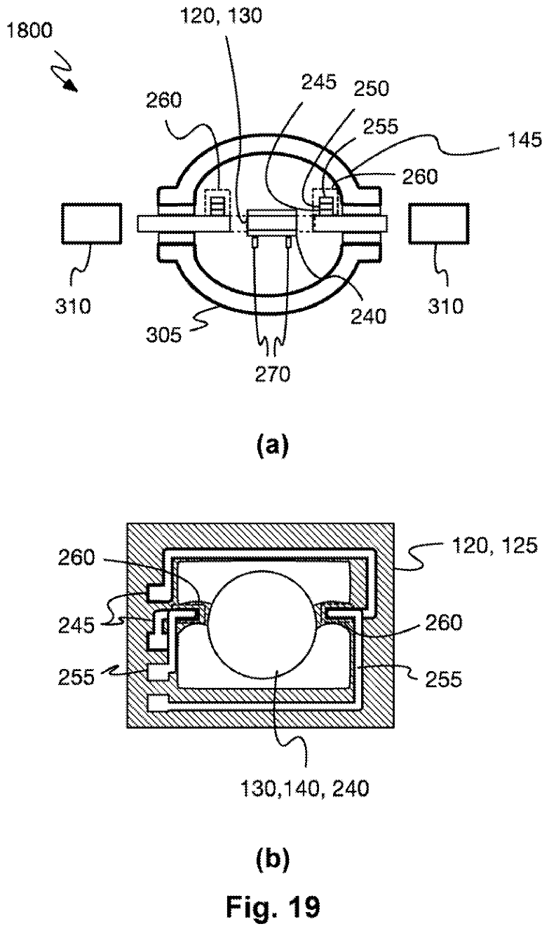

FIG. 19 schematically illustrates an eighteenth exemplary embodiment of a MEMS mirror device according to the invention, in which a magnetic drive device is provided for driving the mirror subregion;

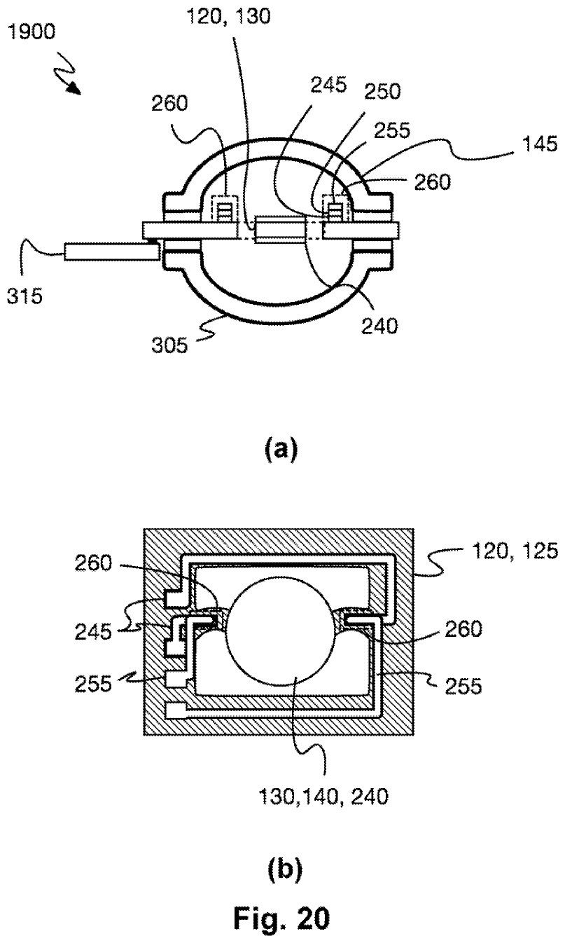

FIG. 20 schematically illustrates a nineteenth exemplary embodiment of a MEMS mirror device according to the invention, in which a piezoelectric actuator external to the capsule is provided as a drive device for driving the mirror subregion;

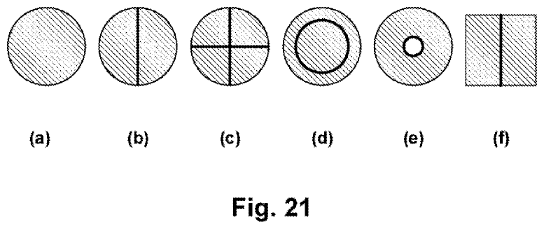

FIG. 21 shows various embodiments for bottom electrode shapes; and

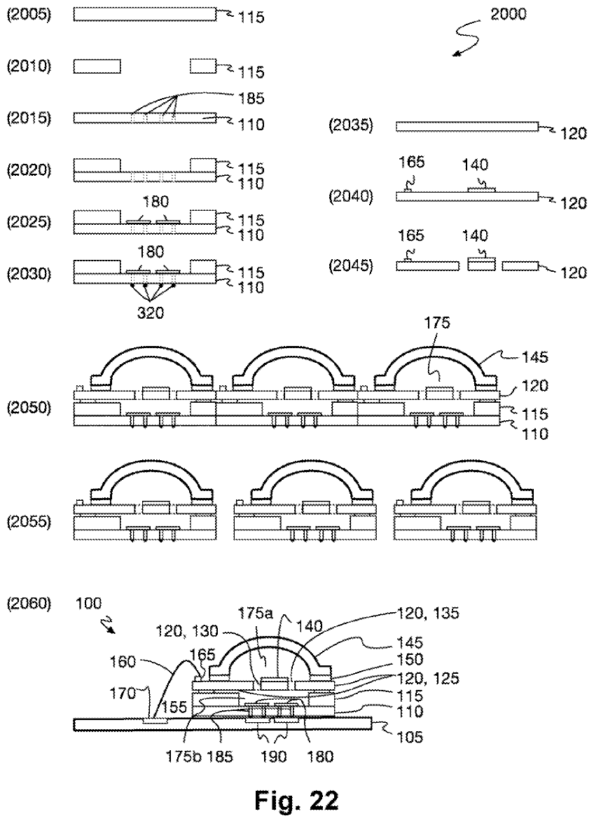

FIG. 22 a diagram illustrating essential production steps of a method according to the invention in accordance with a preferred embodiment.

In the figures, the same reference signs are used throughout for the same or corresponding elements of the invention. The features of the exemplary embodiments described below can in each case be combined with one another as desired, unless this is expressly excluded or would be technically impossible, in particular contradictory.

FIG. 1 illustrates a first exemplary embodiment 100 of a MEMS mirror device. Here, FIG. 1 (a) illustrates a side sectional view of the MEMS mirror device 100, while FIG. 1 (b) illustrates a top view of a glass substrate 120 that forms a first glass substrate of the MEMS mirror device 100 and is arranged horizontally in FIG. 1 (a). A corresponding division into subfigures (a) and (b) will also be used below to illustrate and explain various other embodiments of MEMS mirror devices.

The MEMS mirror device 100 has a piezoelectric actuator 105 as a driving device, which also forms a base plate of the MEMS mirror device 100. On the piezoelectric actuator 105, there is arranged a stacked multilayer structure comprising various substrates stacked on top of each other. The core of this multilayer structure is formed by a first substrate (glass substrate) 120 made of a glass material, which is structured into various interconnected subregions as shown in FIG. 1 (b). These subregions include a frame subregion 125, a mirror subregion 130, and two connecting webs 135 each connecting the mirror subregion 130 to the frame subregion.

The mirror subregion 130 is movably mounted in the frame subregion 125 via the connecting webs 135, which can twist, in such a way that the mirror subregion 130 can perform a two-dimensional oscillating motion relative to the frame subregion 125. The connecting webs 135 thus provide a suspension for the mirror subregion 130. The mirror subregion 130 is provided on one of its main surfaces with a metallic coating 140 in such a way that this metallic coating 140 forms a mirrored reflection surface for deflecting incident electromagnetic radiation, in particular a laser beam, for example in the visible or infrared range of the electromagnetic spectrum.

In particular, the metallic coating 140 may include one or more of the following materials: aluminium (Al), gold (Au), silver (Ag). These materials may have both high long-term durability and good mirror properties. Thus, the mirror subregion 130 or its mirrored reflection surface 140 represents a MEMS mirror whose diameter is typically less than 30 mm, for example 10 mm. The shape of the mirrored reflection surface 140 may be circular, in particular as shown in FIG. 1 (b), but without this being understood as a limitation. In particular, rectangular shapes are also conceivable.

This multilayer structure further includes a second substrate (glass substrate) 145 made of a glass material that can correspond in particular to that of the first glass substrate. The second glass substrate has a dome shape and is hermetically connected to the frame subregion 125 of the first glass substrate 120 by means of a substrate bonding material 150, e.g. a glass frit material, to form a first (in FIG. 1 (a) “upper”) subregion 175a of a cavity 175 surrounding the mirror subregion 130 on both sides thereof.

On the side of the first glass substrate 120 opposite the second glass substrate 145, there is a third substrate 110 serving as a bottom plate in the multilayer structure, as well as a further, fourth substrate 115 between the first glass substrate and the third substrate, which is formed as a spacer or (equivalently) spacer layer. The third and fourth substrates can each be made in particular of a glass material or, for example, also of silicon or another semiconductor material. In particular, however, like the first and second substrates, they can also be formed as glass substrates. Ideally, all glass substrates are made of the same glass material and thus have the same material-dependent coefficient of thermal expansion. Thus, thermal stresses in the multilayer stacked structure of the MEMS mirror device 100 can be avoided.

In other variants of this and other embodiments described below, the third substrate 110 and/or the fourth substrate 115 may in particular be made of a semiconductor material, such as silicon. This in turn has the advantage that, due to the extensive opacity of such materials, the penetration of parasitic radiation into the cavity 175 and in particular to the mirror subregion 130 can thereby be counteracted.

The fourth substrate 115 is structured to include a cavity disposed below the mirror subregion 130 such that, together with its bottom-side boundary provided by the bottom plate 110, it forms a second (in FIG. 1 (a), “bottom”) subregion 175b of the cavity 175.

The respective adjacent individual substrates are hermetically sealed to one another, for example again by means of a substrate bonding material 155, e.g. in the case of two glass substrates to be joined by means of a glass frit material, so that the cavity 175 is hermetically sealed overall. It is preferably evacuated so that a residual gas pressure prevails therein, preferably significantly below normal conditions (101.325 kPa=1013.25 mbar), which is preferably below 10 kPa/10⁺¹ kPa (10⁻¹ mbar), particularly preferably at 10⁻¹ kPa (10⁻³ mbar). Typically, the first to fourth substrates 110, 115, 120, 145 each have the same basic shape, in particular a rectangular shape, although other shapes are equally possible.

The piezoelectric actuator 105 is configured to generate and transmit oscillatory motion to the stack assembly, and in particular to the mirror subregion 130, when electrically actuated. In this manner, the mirror subregion 130 can be excited with its mirror surface 140 to perform a oscillatory motion, particularly a resonant or forced multi-dimensional oscillatory motion such as a Lissajous motion relative to the frame subregion 125. During this oscillatory motion, the mirror subregion 130 can move out of the plane of the first glass substrate 120, in particular by tilting, and in doing so can be immersed in the subregions 175a and 175b of the cavity 175 on both sides. Due to the evacuation of the cavity 175, the remaining friction in the gas is very low, so that only a small, in particular a negligible, damping occurs.

Furthermore, the MEMS mirror device 100 has a capacitive position determination device. The position determination device includes two electrodes between which an electrical capacitance measurement is performed for the purpose of determining the respective current deflection position, in particular orientation, of the mirror subregion 130. A first of the two electrodes is formed by the metallic mirror surface 140, which is thus intended to perform a dual function (deflecting incident electromagnetic radiation; electrode). The second of the two electrodes is formed on the inner surface of the bottom plate 110, in the cavity region 175, as a corresponding metallic coating 180 of the bottom plate 110. In the present example, this bottom electrode 180 is formed as a multi-part structured metallic coating. As can be seen from FIG. 1 (b), the shape of this bottom electrode 180 corresponds in terms of its type and preferably at least approximately also in terms of its size essentially to the shape of the mirror subregion 130, or of its reflective layer or mirror surface 140, which is parallel thereto in the undeflected rest state of the mirror subregion 130.

The bottom electrode 180 is electrically contacted via one or more so-called vias 185 (specifically “through glass vias”, TGV), i.e. connection tunnels filled with electrically highly conductive (conductivity>10⁶ S/m), usually metallic, material, which extend from the bottom electrode 180 through the bottom plate 110 to corresponding connection pads 190 on the piezo actuator 105. The mirror electrode 140, in turn, is electrically connected via a rewiring layer to a connection pad 165 disposed on the first glass substrate 120 outside of the dome formed by the second glass substrate, and from there is electrically connected via a bonding wire 160 to another connection pad 170 on the piezoelectric actuator 105. Thus, the mirror electrode as a whole is electrically contacted via the connection pad 170. Consequently, an electrical capacitance measurement used to determine the position of the mirror subregion 130 can be made between the connection pads 190 and 170.

Segmentation of the bottom electrode 180 in FIG. 21 (alternatively or additionally also of the mirror electrode 140) enables differential readout and thus improved signal quality (e.g. lower sensitivity to temperature influences) during capacitance measurement. Furthermore, a segmentation of the bottom electrode 180 in connection with embodiments in which the rear side of the mirror subregion facing the bottom plate 110 is also at least partially mirrored can offer the advantage that this mirrored rear side area can also be read out without being obstructed by the bottom electrode, can be irradiated with additional electromagnetic radiation, in particular a laser beam, from the bottom side of the MEMS mirror device 100, for example in order to optically measure the position of the mirror subregion 130 or in order to use the mirror subregion functionally also from its rear side, in particular for electromagnetic scanning or projection.

The bottom electrode is connected via 3D through-glass vias (TGV) in the bottom wafer, which enable an electrical vertical connection to the substrate contact. Instead of the structured metallization of the first glass substrate shown here, a full-surface metallization of the first glass substrate is just as good for implementing the reflection layer on the one hand and the electrode for the position sensor to be read out on the other. The advantage of an unstructured metallization is the saving of a lithography layer or another structuring method, which can make the production process even more cost-effective. In addition to or instead of using glass frit to connect the respective adjacent substrates, other methods such as glass direct bonding, eutectic bonding or metal direct bonding can also be used.

In FIG. 2, the simplified beam path of the incident and outgoing electromagnetic radiation is shown in the case of (a) a dome-shaped second glass substrate 145 as described above in connection with the embodiment according to FIG. 1 as an example, and (b) in the case of a second glass substrate arranged in sections planar and in sections angled with respect to the rest position of the mirror subregion. The structure of the MEMS mirror device 100 in FIG. 2(a) is the same as that in FIG. 1. The same applies to the structure of the MEMS mirror device 100 in FIG. 2(b) except for the different shape of the second glass substrate 145. During operation of the MEMS mirror device 100, electromagnetic radiation, which may be provided, for example, as a laser beam and may include, in particular, light components in the visible or infrared range of the electromagnetic spectrum, is directed as a beam L1 through the respective second glass substrate 145 of FIGS. 2(a) and 2(b), respectively, onto the mirror surface 140 of the mirror subregion 130, where it is reflected in accordance with the law of reflection. This results in a reflected beam L2 that exits the MEMS mirror device 100 again through the second glass substrate 145. However, a small portion of the incident radiation of the beam L1 does not fall on the mirror surface 140, but is already reflected on the surface of the second glass substrate 145 when it hits it, resulting in a further beam L3 for this reflected radiation. However, due to the particular respective geometry or arrangement of the surface of the second glass substrate 145, the beam L3 is at least substantially deflected in one or more different directions than the beam L2, so that it does not significantly overlap and thus interfere with the beam L2. This is particularly relevant in the case where the beam L1/L2 is provided for projection purposes.

FIG. 3 shows a second embodiment 200 of a MEMS mirror device according to the invention, which is based on the first embodiment 100 of FIG. 1. It differs from the embodiment 100 in particular in that instead of only the mirror subregion 130 or even only a part thereof, the entire side of the first glass substrate 120 facing the second glass substrate 145 is provided with the metallic coating 140, although it is sufficient in this case that only the mirror subregion 130 or a part thereof continues to be mirrored. Thus, during production, a process for patterning the metallic coating 140 may be omitted, which may help to reduce production complexity and effort, production time, and thus associated production costs.

FIG. 4 shows a third embodiment 300 of a MEMS mirror device according to the invention, which in turn builds on the first embodiment 100 of FIG. 1, or alternatively (not shown) also on the second embodiment 200 of FIG. 2. It differs from the embodiments 100 or 200 in particular in that one or more residual gas getter elements 195 are additionally arranged in the cavity 175, in particular in its bottom subregion 175b. The residual gas getter elements 195 are material structures that contain a chemically reactive material (such as Ti) that is suitable for chemically binding any gas particles present in the cavity, in particular nitrogen, oxygen, hydrogen or water molecules, to the respective residual gas getter element and thus improving the quality of the vacuum in the cavity 175, in particular the initial quality as well as the long-term maintenance of the vacuum. Thus, low damping and thus high oscillation amplitudes of the oscillatory motion of the mirror subregion 130 and consequently high quality factors of the MEMS mirror device 300 can be achieved.

FIG. 5 shows a fourth embodiment 400 of a MEMS mirror device according to the invention, which in turn builds on the first embodiment 100 of FIG. 1, or alternatively (not shown) also on one of the other embodiments 200 or 300 already explained. It differs from the embodiment 100 in particular in that the bottom electrode 180 is arranged on the outside of the bottom substrate 110 and thus outside the cavity 175. This has the advantage of eliminating the vias 185 and associated process steps in the fabrication of the MEMS mirror device 400 compared to the MEMS mirror device 100. Instead, the bottom electrode 180 can in particular also be formed as part of a metallization of a redistribution layer (RDL) on the bottom side of the bottom substrate 110 or on the top side of an underlying further layer, such as a printed circuit board (PCB), or the piezoelectric actuator 105. Thus, in particular, the assembly complexity of the MEMS mirror device 400 and thus its production times and production costs can be reduced accordingly. According to a variant thereto, the embodiments of FIGS. 3 and 5 may also be present in combination, such that a first glass substrate 120 coated over its entire surface with a metallic coating 140 is combined with the via-less variant of the bottom electrode 180, with the metallic coating 140 also serving as the top electrode.

FIG. 6 shows a fifth embodiment 500 of a MEMS mirror device according to the invention, which is based in particular on the fourth embodiment 400 of FIG. 4. It differs from embodiment 400 in particular in that the bottom electrode 180 is omitted and replaced by a counter electrode 205 to the mirror electrode 140, which is also arranged on the first glass substrate 120. In particular, it may be provided in ring form around the mirror subregion 130 extending on the frame subregion 125. Overall, this results in a lateral capacitor. This has the advantage that the counter electrode 205 can be produced as part of the same layer as the mirror layer or mirror electrode 140, again reducing production complexity and production effort. This in turn reduces manufacturing complexity and effort.

FIG. 7 shows a sixth embodiment 600 of a MEMS mirror device according to the invention, which is based in particular on the first embodiment 100 of FIG. 1. It differs from the embodiment 100 in particular in that instead of the dome-shaped second glass substrate 145, a planar cover substrate 215, which is indirectly connected to the first glass substrate 120 via a spacer substrate 210, is provided. Planar cover substrates 215 are less complex to production and thus less expensive than three-dimensional, particularly dome-shaped cover substrates such as the second glass substrate 145. Such planar designs are particularly suitable for applications in which radiation reflected from the cover substrate itself can be separated from radiation deflected by the MEMS mirror by some other configuration, such as one or more apertures or spatially varying refractive indices in the substrate material.

FIG. 8 shows a seventh embodiment 700 of a MEMS mirror device according to the invention, which is based in particular on the sixth embodiment 600 of FIG. 7. It differs from embodiment 600 in particular in that the bottom electrode 180 is designed as an electrically “floating” electrode, i.e. as an electrode that is not contacted and thus not set to an externally applied electrical potential during operation. This has the advantage that the time required for the production of such a contact, in particular for the production of the vias 185 and the underlying contact pads 190, can be saved, while a capacitance measurement, in particular a measurement of mirror position-dependent capacitance changes relevant for position determination, remains possible.

FIG. 9 shows an eighth embodiment 800 of a MEMS mirror device according to the invention, which can be implemented as a respective modification of each of the other embodiments described herein, in particular also of the seventh embodiment 700 of FIG. 8. It differs above all in that the, in particular hermetic, encapsulation of the MEMS mirror device is not, at least not necessarily, already effected by the multilayer stack structure itself, but by means of a separate housing (“second-level package”), for example of the known TO or CDIP type. The package has, in particular, side walls 220, which are preferably made of a metal or ceramic material, as well as a glass substrate 225 lying above it, which serves as a window for the incident radiation and the radiation deflected at the MEMS mirror 140 and which can have, in particular, a planar shape.

The bottom electrode 180 and optionally also, as shown, one or more residual gas getter elements 195, may thereby be provided on the inside of the bottom of the package (such as CDIP or TO packages), which may in particular be formed by the piezoelectric actuator 105. An advantage of this embodiment is that it makes it particularly easy to provide a package that can be soldered (in particular by (through-hole technology, THT, or by surface-mount technology, SMT)), including the MEMS mirror device itself, resulting in easier assembly in a system environment, for example in a projection system constructed from multiple assemblies.

FIG. 10 shows a ninth embodiment 900 of a MEMS mirror device according to the invention, which is based in particular on the third embodiment 300 of FIG. 4. It differs from embodiment 300 in particular in that the bottom electrode 180 and the residual gas getter elements 195 coincide. This means that the bottom electrode 180 simultaneously has the property of chemically binding residual gas particles in order to increase or ensure the quality of the vacuum in the cavity 175. In particular, titanium or another titanium-containing material can be used as a suitable material that can fulfill this dual function. Due to the dual function of the bottom electrode 180/195 according to this embodiment, the complexity of the structure of the MEMS mirror device as well as the production effort required for its production and thus the associated production costs can be further reduced.

FIG. 11 shows a tenth embodiment 1000 of a MEMS mirror device according to the invention, which can be based on any of the other embodiments described herein, in particular on the first embodiment 100 of FIG. 1. It differs from embodiment 100 in particular in that the mirror subregion 130 is thickened in thickness by connecting (bonding) to at least one further substrate 230, which will be referred to herein as the reinforcing substrate. The mirror subregion thus has a total of at least two substrates, preferably glass substrates. These substrates can in particular have different thicknesses, which can be used in particular to build springs (connecting webs 135) and mirror subregions of different thicknesses from them, depending on the type of construction and application. Overall, this embodiment 1000 allows to increase the number of excitable degrees of freedom for the oscillatory motion of the mirror subregion, in particular by local changes of the mechanical stiffness. Among other things, this also allows the resonant frequency of the spring-mirror system to be optimally adjusted as well as the dynamic deformation of the mirror subregion 130 to be reduced. This in turn can have a positive effect on the beam quality of the deflected electromagnetic radiation L2.

FIG. 12 shows an eleventh embodiment 1100 of a MEMS mirror device according to the invention, which is based on any of the other embodiments described herein, in particular on the first embodiment 100 of FIG. 1. In particular, it differs from embodiment 100 in that all of the glass substrates are made of one, ideally the same, quartz glass material. Optionally, as shown, another spacer/spacer substrate 235 may be provided between the dome-shaped second glass substrate 145 and the first glass substrate 120 to increase the volume of the upper cavity region 175a. This embodiment is particularly advantageous when high laser powers are used at which silicate glass, especially borosilicate glass, is no longer usable. Because of the poorer thermal matching of silicon or other semiconductor materials to glasses, the entire substrate stack of substrates 110, 115, 120, 235 and 145 in this design consists of quartz glass.

Thus, an advantage of this embodiment 1100 is in particular that this MEMS mirror device can be used very well in applications with high laser power, in particular laser-assisted material processing, since it is stable at high temperatures and its substrate material in particular has a high melting point. The enlargement of the cavity 175, in particular the cavity region 175a above the mirror surface 140, also increases the thermal robustness of the structure. Furthermore, quartz glasses are subject to particularly low aging in the face of high laser radiation power.

FIG. 13 shows a twelfth embodiment 1200 of a MEMS mirror device according to the invention, which is based in particular on the first embodiment 100 of FIG. 1. It differs from the embodiment 100 in particular in that the bottom-side rear side of the mirror subregion 130 is coated with an electrically highly conductive (conductivity>10⁶ S/m) layer 240, in particular a metallic coating, which serves as a counter-electrode (top electrode) to the bottom electrode 180. Thereby, this rear electrode layer 240 can serve as a counter electrode instead of or in addition to the mirror surface 140. Ideally, the terminal pad 165 is correspondingly formed in the same layer as the rear electrode layer 240 so that it is arranged on the bottom surface of the first glass substrate 120. The reduced distance between the two electrodes 180 and 240 can be used to increase the detection sensitivity of the capacitive position determination device.

FIG. 14 shows a thirteenth embodiment 1300 of a MEMS mirror device according to the invention, which is based in particular on the fifth embodiment 500 of FIG. 6. It differs from embodiment 500 in particular in that instead of the lateral capacitor, a piezoelectric element is provided for determining the position of the mirror subregion 130. The piezoelectric element has a layer 250 of a piezoelectric material, which is enclosed in the sense of a “sandwich” by a bottom electrode 245 and a top electrode 255 and together with these forms a piezoelectric element, which is arranged on the edge subregion 125 of the first glass substrate 120 in the region of the connecting webs 135 or adjacent to these. FIG. 14 (b) shows in detail a possible geometry of the piezoelectric element 260 including the bottom electrode 245 and the top electrode 255 with their leads and connection pads on the first glass substrate 120.

When, during operation of the MEMS mirror device 1300, the mirror subregion 130 is deflected and thus changes its position, this motion is transmitted to the piezoelectric element(s) 260 via the connecting webs 135, resulting in a deformation of the piezoelectric material 250 and subsequently in the generation of a measurable electrical voltage between the bottom electrode 245 and the top electrode 255 due to the known piezoelectric effect. Thus, by means of measuring this voltage, the position of the mirror subregion 130 can be determined. In this way, even a particularly precise position determination is possible, in particular one with a good signal quality with a large signal-to-noise ratio (SNR).

In addition, the or each piezoelectric element 260 can also be used as a drive device by applying a suitable voltage to it, utilizing the inverse piezoelectric effect to cause a oscillatory motion which, due to the mechanical coupling, is transmitted via the connecting webs 135 to the mirror subregion 130, causing it to oscillate. The piezoelectric element(s) 260 can thus combine multiple functionalities in the sense of “dual-use”. In particular, in this case, a further drive device, in particular the bottom piezoelectric actuator 105, can be dispensed with. The latter can in particular be replaced by a printed circuit board 265 or be omitted altogether.

FIG. 15 shows a fourteenth embodiment 1400 of a MEMS mirror device according to the invention, which is based in particular on the fifth embodiment 500 of FIG. 6. It differs from embodiment 500 in particular in that instead of capacitive position determination, magnetic position determination is provided for the mirror subregion 130. For this purpose, one or more permanent magnets 270 are provided on the mirror subregion 130, preferably on its bottom rear side, and a detection coil 275 with connection pads 280 for contacting is provided on the frame subregion 125.

Additionally or alternatively, the permanent magnetic material may be embedded in the substrate of the mirror subregion 130 itself. The sinking of magnetic material into glass pockets can be enabled, for example, via the insertion of sub-mm magnetic spheres (e.g. made of rare earth magnets SmCo), which are fixed in the holes, e.g. via an “atomic layer deposition” process.

When the mirror subregion 130 is deflected, particularly when it performs an oscillatory motion, an electrical voltage is generated in the detection coil 280 due to induction, which can be measured to perform at least relative position determination for the mirror subregion 130. The detection coil 280 may alternatively be disposed in or on the bottom substrate 110 or on an external substrate.

By exploiting the magnetic interaction, particularly good signal-to-noise ratios (SNR) can be achieved for position determination. In addition, a separate drive of the mirror subregion 130, in particular by means of the piezoelectric actuator 105, can also be dispensed with here (cost saving) by temporarily using the detection coil 280 as an excitation coil via the known Lorenz force to exert a force effect on the permanent magnets 270, which in turn can cause an oscillatory motion of the mirror subregion 130. In particular, the piezoelectric actuator 105 (shown here) may again be replaced by a printed circuit board 265 as in FIG. 14 or may be omitted altogether.

In addition to inductive detection, Hall, xMR, fluxgate, or other magnetic field sensors can be used, which can be arranged or inserted, in particular, on the first glass substrate 120, the bottom substrate 110, or an external substrate.

FIG. 16 shows a fifteenth embodiment 1500 of a MEMS mirror device according to the invention, which is based in particular on the fourteenth embodiment 1400 of FIG. 15. It differs from embodiment 1400 in particular in that the hermetic encapsulation, in particular by means of the second glass substrate 145, is omitted. Accordingly, no residual gas getter elements 195 are typically provided here. The first glass substrate 120 is attached to a base substrate via a spacer substrate 115, which may again in particular be a piezoelectric actuator 105 or also a printed circuit board (PCB) or another carrier substrate.

Here, the mirror subregion 130 is driven magnetically, for which purpose one or more permanent magnets 270 are arranged on the mirror subregion 130, preferably—as shown—on its bottom rear side. One or more drive and detection coils 285 are arranged opposite these permanent magnets 270. During operation of the MEMS mirror device 1500, these drive and detection coils 285 enter into magnetic interaction with the permanent magnets 270. If this magnetic arrangement is thereby used as a drive device for the mirror subregion 130, a—typically variable—magnetic field is generated in the drive and detection coils 285 by charging with a suitably defined electric current, which field acts on the permanent magnets 270 and, via these, sets the mirror subregion 130 into a desired oscillatory motion.

On the other hand, if, at other times, the same arrangement is used to detect the respective current position of the mirror subregion 130, the drive and detection coils 285 serve as induction coils in which, due to the magnetic interaction with the permanent magnets 270 moved as a result of the oscillatory motion of the mirror subregion 130, an electrical voltage is induced which can be measured for the purpose of determining the position. Alternatively, the corresponding induction current or a quantity dependent thereon can be measured.

This embodiment is particularly, but not exclusively, suitable for quasi-static MEMS mirror devices. In particular, due to the omission of encapsulation, it also enables alternative projection principles and thus additional applications, such as laser welding, laser cutting and other types of laser microprocessing.

FIG. 17 shows a sixteenth embodiment 1600 of a MEMS mirror device according to the invention, which is based in particular on the twelfth embodiment 1200 of FIG. 13. It differs from embodiment 1200 in particular in that the capacitive position determination is or can be omitted and instead an optical position determination device is provided, which includes an optical transmitter 290 (e.g., laser diode) and an optical receiver 295 (e.g., photodiode). In addition, the rear metal coating 240 of the mirror subregion 130 is also formed as a MEMS mirror so that it can reflect a measurement radiation 300 emitted from the transmitter 290 in the sense of an image, thereby deflecting it toward the optical receiver 295. The oscillatory motion of the mirror subregion 130 thus modulates the reflected measurement radiation 300 received at the optical receiver, so that the signal measured at the receiver 295 provides a measure of the current position of the mirror subregion 130.

So that the measuring radiation can reach the rear mirror 240 and subsequently the receiver 295, the bottom substrate 110 is designed as a glass substrate. Insofar as—as shown—a drive device, in particular a piezoelectric actuator 105, is also provided on the bottom side, this is arranged in such a way or its shape is designed in such a way that the beam path of the measuring radiation 300 is not or only negligibly affected by the drive device. The advantages of this embodiment include, in particular, that no electrical substrate feedthroughs (e.g., TGVs) are required and that the MEMS mirror device 1600 is particularly robust and can be produced at low cost. In addition, a particularly high accuracy in position determination can be realized by means of the above-mentioned optical measurement method.

FIG. 18 shows a seventeenth embodiment 1700 of a MEMS mirror device according to the invention, which is based in particular on the thirteenth embodiment 1300 of FIG. 14. It differs from embodiment 1300 in particular in that the first glass substrate 120 is encapsulated not only on one side, but on both sides in each case by a dome-shaped glass substrate 145 or 305. In addition, the rear side of the mirror subregion 130 is again also formed as a MEMS mirror.

The combination of these modifications allows the mirror subregion 130 to be used on both sides as a deflecting mirror for electromagnetic radiation, thereby significantly extending the illuminable scan range, particularly for one or more axes of oscillation of the mirror subregion in each case up to nearly 360°, with substantially only the angular regions covered by the first glass substrate itself limiting the achievable scan range angle. Furthermore, the bottom dome-shaped cavity subregion 175b, which is defined by the glass substrate 305, allows an additional spacer substrate 115 to be dispensed with. In particular, driving the mirror subregion 130 and determining its current position may, but is not limited to, again be accomplished by means of one or more piezoelectric elements 260. The connections of the piezoelectric elements 260 are not explicitly shown in FIG. 18 for simplicity of drawing.

FIG. 19 shows an eighteenth embodiment 1800 of a MEMS mirror device according to the invention, which is based in particular on the seventeenth embodiment 1700 of FIG. 18. It differs from embodiment 1700, in particular, in that a magnetic drive device is provided for driving the mirror subregion 130. The magnetic drive device includes one or more permanent magnets 270 arranged on the mirror subregion, for example on its rear side. It further includes a drive coil 310 disposed outside the encapsulation, which is configured such that when supplied with a suitably selected alternating electric current, a magnetic field is generated that exerts a magnetic force on the permanent magnet(s) 270, thereby causing the mirror subregion to oscillate.

In particular, the piezoelectric elements 260 can again be used as position determining devices, or optionally as additional drive devices. The advantages of the double-sided dome-shaped encapsulation of embodiment 1700 of FIG. 18, are also retained here. The permanent magnet(s) 270 may again be alternatively or additionally integrated into the mirror subregion 130 of the first glass substrate 120, as explained previously in connection with embodiment 1400 of FIG. 15. The connections of the piezoelectric elements 260 are again not explicitly shown in FIG. 19 for simplification of the drawing.

FIG. 20 shows a nineteenth embodiment 1900 of a MEMS mirror device according to the invention, which is based in particular on the seventeenth embodiment 1700 of FIG. 18. It differs from embodiment 1700 in particular in that a piezoelectric actuator 315 external to the capsule is provided as a drive device for driving the mirror subregion 130, which is coupled to the first glass substrate 120, in particular directly. In this way, particularly high forces can be transmitted to the first glass substrate 120, which can be used in particular to effect higher deflection angles or oscillation amplitudes than would be possible with a weaker drive or a weaker force coupling.

The piezoelectric elements 260 can again be used here as position determining devices, optionally also or instead as additional drive devices. The advantages of the double-sided dome-shaped encapsulation of embodiment 1700 from FIG. 18, are also retained here. The connections of the piezoelectric elements 260 are again not explicitly shown in FIG. 20 for simplification of the drawing.

FIG. 21 shows various embodiments for shapes of bottom electrode 180:

(a) full circular (simple processing),

(b) double segmentation semicircle (differential interconnection, better SNR),

(c) quarter segmentation pie shape (differential interconnection, better SNR),

(d) double segmentation ring shape (differential interconnection, better SNR),

(e) non segmented ring shape with hole (optical aperture for mirror subregion rear side use with mirror surface 240)

f) as b) but in rectangular shape (depending on cavity shape and mirror geometry, this allows optimum area coverage).

Segmentation of the electrode(s) allows, in particular, differential interconnection to optimize capacitance measurement.

FIG. 22 shows a diagram illustrating essential fabrication steps according to a preferred embodiment 2000 of a method according to the invention for production MEMS mirror devices, in particular MEMS mirror devices 100 according to FIG. 1. In each case in a correspondingly modified or supplemented form, the steps or sequences of steps of this method can also be used for production further embodiments 200 to 1900, in particular those described in detail above.

The process steps 2005 to 2045 and 2060 described in detail below each represent only one MEMS mirror device 100 or its precursors for the purpose of clarity. However, within the scope of the process 2000, a simultaneous processing of several such MEMS mirror devices 100 or of their intermediate products on the basis of a common substrate or substrate stack (cf. step 2050, in which several such intermediate products are arranged next to each other on the basis of common substrates) actually takes place (in analogy to chip production in the semiconductor industry, in which a plurality of chips are processed simultaneously on a single wafer) up to and including step

A first method section comprising steps 2005 to 2030 relates to the fabrication of a base assembly supporting the first glass substrate 120. This first method section begins with a step 2005, in which a disc-shaped substrate 115 is provided, which, depending on the design, may in particular be made of a glass material or of a semiconductor material, such as silicon, and which may in particular have a round wafer shape or a rectangular panel shape.

Next, a glass structuring process 2010, which may in particular be or include a laser-based etching process, such as a laser induced deep etching, (LIDE) etching method, is used to structure the substrate 115 as a spacer substrate 115. In this process, a cavity is formed in the substrate 115 for each MEMS mirror device 100 to be fabricated, which later defines a side wall of the respective cavity region 175b. The disc-shaped substrate 115 from step 2005 is selected to be large enough so that a plurality of laterally adjacent MEMS mirror devices 100 can be fabricated on its base (cf. step 2050). In particular, the substrate 115 may have an area of 100 cm², preferably 1000 cm² or more.

In a further step 2015, electrical contact holes (vias) 185 for contacting the respective bottom electrode 180 of the later MEMS mirror device 100 are formed in a further substrate 110, which will later form the respective bottom plates of the MEMS mirror devices 100, in a known manner, for which, depending on the substrate material used for the substrate 110, an appropriately suitable structuring process, such as a dry etching process (e.g., reactive ion etching, RIE) or again, for example, a LIDE method can be selected.

After forming the vias 185 in the bottom substrate 110, this is connected to the spacer substrate 115 resulting from step 2010 by means of a suitable, usually material-dependent, substrate bonding process, for example a wafer bonding process. If both substrates 110 and 115 are glass substrates, a glass frit bonding process can be used here in particular.

Then, in a further step 2025, one or more bottom electrodes 180 are formed within the cavities formed by the spacer substrate 115 and on bottom substrate 110 for each MEMS mirror device to be produced, so that they are in electrical contact with at least one associated via 185 each and are contacted in this way.

Finally, in a further step 2030, solder balls (solder bumps) are formed at the ends of the vias 185 on the side of the bottom substrate 110 opposite or briefly opposite the bottom electrodes 180, in order to enable subsequent contacting, in this case specifically with a piezoelectric actuator 105. Thus, the base assembly, but not yet singulated, is prefabricated as an intermediate product.

In a second process step, the first glass substrate 120, which in particular supports the MEMS mirror 140, is produced. First, a suitable glass substrate 120 is provided in step 2035, the dimensions of which may correspond in particular to those of the substrate 110 or 115. The glass material may in particular be a silicate glass, such as a borosilicate glass, or a quartz glass.

A metallic coating is selectively deposited on the glass substrate 120 at a suitable location for each MEMS mirror device 100 to be produced, for example on the basis of a lithography and structuring process, in order to create, on the one hand, a mirror surface 140 for the MEMS mirror and, on the other hand, one or more connection pads 165 for electrical contacting of the mirror surface 140. The electrical contacting of the mirror surface 140 allows the mirror surface 140 to also be used as a top electrode for capacitive position determination of the MEMS mirror or the mirror subregion 130 of the first glass substrate 120. As part of this metallization process, the mirror surface 140 may also be machined, in particular polished, to produce the desired mirror properties.

Next, the first glass substrate 120 is structured, which in particular can again be carried out by means of one or more of the aforementioned structuring processes, in particular a LIDE process. In this process, a frame subregion 125, a mirror subregion 130, and one or more connecting webs 135 extending between these two regions are formed in the glass substrate 120 for each MEMS mirror device 100 to be produced (cf. shape of the glass substrate 120 in FIG. 1 (b)), so that a mirror subregion 130 capable of oscillation in at least two spatial dimensions is formed overall as a MEMS mirror. A typical diameter of the mirror surface 140 is, for example, in the range of 5 to 50 mm, although other expansions, in particular those above this, are also possible, for example also in the case of non-circular mirror shapes.

In a third method section, which is summarized as step 2050, the base assembly with the substrates 110 and 115 generated in the first process section, the structured first glass substrate 120 generated in the second process section and, for each MEMS mirror device 100 to be produced, a dome-shaped second glass substrate 145 are stacked on top of one another as shown and joined to one another so that a hermetically encapsulated cavity 175 is formed around each mirror subregion 130. In the course of the third method section 2050, this cavity 175 can in particular also be evacuated, for which purpose this process section can in particular also take place under appropriate vacuum conditions. As a result of the third method section 2050, a plurality of intermediate products connected to one another within the framework of the same stack structure and arranged next to one another results, each of which essentially already corresponds to one of the MEMS mirror devices 100 to be produced.

In a fourth method section, shown here as step 2055, these intermediate products are separated into individual assemblies.

Finally, in a fifth method step, which is summarized here as step 2060, a corresponding finished MEMS mirror device 100 is produced from one of the intermediate products in each case, to which end a piezoelectric actuator 105 is added, in particular on the bottom side, as a drive device for the mirror subregion 130 with corresponding electrical connections, and the corresponding electrical contacting of the bottom electrode(s) 180 and of the top electrode, which also serves as a mirror surface 140, is carried out.

While several exemplary embodiments have been described above, it should be noted that a large number of variations thereon exist. It should also be noted that the exemplary embodiments described are only non-limiting examples, and it is not intended thereby to limit the scope, applicability, or configuration of the devices and methods described herein. Rather, the foregoing description will provide guidance to those skilled in the art for implementing at least one exemplary embodiment, wherein it is understood that various changes in the operation and arrangement of the elements described in an exemplary embodiment may be made without departing from the subject matter set forth in each of the appended claims as well as its legal equivalents.

### LIST OF REFERENCE SIGNS

100 first embodiment of a MEMS mirror device
200 second embodiment of a MEMS mirror device
300 third embodiment of a MEMS mirror device
400 fourth embodiment of a MEMS mirror device
500 fifth embodiment of a MEMS mirror device
600 sixth embodiment of a MEMS mirror device
700 seventh embodiment of a MEMS mirror device
800 eighth embodiment of a MEMS mirror device
900 ninth embodiment of a MEMS mirror device
1000 tenth embodiment of a MEMS mirror device
1100 eleventh embodiment of a MEMS mirror device
1200 twelfth embodiment of a MEMS mirror device
1300 thirteenth embodiment of a MEMS mirror device
1400 fourteenth embodiment of a MEMS mirror device
1500 fifteenth embodiment of a MEMS mirror device
1600 sixteenth embodiment of a MEMS mirror device
1700 seventeenth embodiment of a MEMS mirror device
1800 eighteenth embodiment of a MEMS mirror device
1900 nineteenth embodiment of a MEMS mirror device
2000 embodiment of a production method for MEMS mirror devices
105 Piezoelectric actuator
110 Third substrate, bottom plate
115 Fourth substrate, spacer layer
120 First (glass) substrate
125 Frame subregion
130 Mirror subregion
135 Connecting webs
140 Metallic mirror coating, mirror electrode
145 Second (glass) substrate, dome-shaped
150 Substrate bonding material, i.e. Glass frit
155 Further substrate bonding material, i.e. Glass frit
160 Bonding wire
165 Connection pad on first (glass) substrate 120 for connecting the upper electrode (top electrode) 140
170 Connection pad on piezoelectric actuator 105 for connecting the upper electrode 140
175a Upper area of the cavity 175
175b Lower area of the cavity 175
180 Structured, if necessary multi-part bottom electrode
185 Vias (Through-Glass Vias, TGVs) with solder bumps for contacting the piezoelectric actuator
190 Connection pads on piezoelectric actuator 105 for connection of bottom electrode 180
195 Residual gas getter elements
205 Upper electrode on frame subregion
210 Spacer/spacer substrate
215 Planar cover substrate
220 Side walls
225 Planar glass substrate, window substrate
230 Reinforcement substrate for mirror subregion
235 Further Spacer/spacer substrate
240 Rear electrode layer, in some embodiments rear side mirrors
245 Bottom electrode for piezoelectric material 250
250 Piezoelectric material layer
255 Top electrode for piezoelectric material 250
260 Piezoelectric element with piezoelectric material 250, bottom electrode 245 and top electrode 255
265 Printed circuit board
270 Permanent magnets
275 Detection coil
280 Connection pad for detection coil
285 Detection and drive coils
290 Optical transmitter
295 Optical receiver
300 Measuring radiation
305 Dome-shaped (bottom) glass substrate
310 External drive coil
315 Piezoelectric actuator external to the capsule
320 Solder bumps
L1 Incident light beam
L2 Light beam reflected on dome of second glass substrate
L3 Light beam reflected at the mirror

1. A MEMS mirror device (100) for variable deflection of an incident electromagnetic beam (L1), wherein the MEMS mirror device (100) has a disk-shaped first glass substrate (120) structured into several subregions with a mirror subregion (130) designed at least partially as a MEMS mirror for reflecting electromagnetic radiation, and a frame subregion (125) surrounding the mirror subregion (130) at least in sections;
wherein the mirror subregion (130) is formed as a subregion of the first glass substrate (120) suspended so as to be capable of oscillating in several dimensions relative to the frame subregion (125) by means of at least one connecting element (135) connecting the mirror subregion (130) and the frame subregion (125).

2. The MEMS mirror device (100) according to claim 1, further comprising:
a second glass substrate (145) directly or indirectly connected to the first glass substrate (120) so as to cooperate therewith to form a cavity (175) surrounding the mirror subregion (130) on at least one side of the first glass substrate (120), into which the immersing mirror subregion (130) is capable of oscillatory motion.

3. The MEMS mirror device (100) according to claim 2, wherein the second glass substrate (145) has a dome shape at least in sections.

4. The MEMS mirror device (100) according to claim 2 or 3, further comprising:
a third substrate (110; 305) directly or indirectly connected to the first glass substrate (120) on its side opposite the second glass substrate (145) in such a way that, together with the second glass substrate (145), it forms the cavity (175) in such a way that it surrounds the mirror subregion (130) on both sides in such a way that the mirror subregion (130) can execute the oscillatory motion in the cavity (175).

5. The MEMS mirror device (100) according to claim 4, wherein the cavity (175) is formed as a gas-tight cavity (175) in which a gas pressure lower than normal conditions prevails.

6. The MEMS mirror device (200) according to claim 5, further comprising:
a residual gas getter element (195) comprising a chemically reactive material that is disposed in the cavity (175) and is configured to chemically bind any gas particles present in the cavity (175) to the residual gas getter element (195).

7. The MEMS mirror device (100) according to any one of claims 2 to 6, further comprising one or more fourth substrates (115) collectively forming a spacer layer through which the respective indirect connection of the second glass substrate (145) or the third substrate (110) to the first glass substrate (120) occurs.

8. The MEMS mirror device (1700) according to any one of the preceding claims, wherein the mirror subregion (130) is formed as a double-sided MEMS mirror (140, 240).

9. The MEMS mirror device (1700) according to claim 8 and to any one of claims 4 to 7, wherein the third substrate (305) has a dome shape at least in sections.

10. The MEMS mirror device (100) according to any one of the preceding claims, wherein the first glass substrate or, optionally, one of the further glass substrates is made of a silicate-based glass material, a quartz glass, or a glass material comprising two or more such glass materials.

11. The MEMS mirror device (100) according to any one of the preceding claims, further comprising a position determination device for determining a current deflection position of the mirror subregion (130).

12. The MEMS mirror device (100) according to claim 11, wherein the position determination device is configured to utilize at least one of the following measurement principles to determine the position of the mirror subregion (130):
magnetic induction due to magnetic interaction between a permanent magnet (270) and a magnetic field sensor (275), wherein the permanent magnet (270) is disposed on or in the mirror subregion (130) and the magnetic field sensor (275) is disposed separately from the mirror subregion (130), or vice versa;
generation of an electrical measuring voltage at a piezoelectric element (260) mechanically coupled to the mirror subregion (130) or its suspension (135);
optical position determination by means of an optical transmitter (290), which transmits electromagnetic radiation onto the mirror subregion (130), and an optical receiver (295), which measures the radiation thereby reflected from the mirror subregion (130);
electrical capacitance measurement between two electrodes (140, 180) arranged on the MEMS mirror device in such a way that the electrical capacitance measurable between the two electrodes (140, 180) depends on the current deflection position of the mirror subregion (130)
use of at least one strain gauge to measure a state of at least one connecting element (135).

13. The MEMS mirror device (100) according to claim 12, wherein, in the case of electrical capacitance measurement, one of the electrodes is formed in one of the following ways:
as a metallic layer (140) on or in the mirror subregion (130), which at least in sections simultaneously forms the MEMS mirror for reflecting electromagnetic radiation (L1);
as a metallic layer (240) on or in the mirror subregion, which is formed separately from the mirror surface forming the MEMS mirror;
as a metallic layer (205) on or in the frame subregion (125) of the first glass substrate;
as at least one electrode element (180) formed on one side of the third substrate (110);
as an electrode (180) structured into several separate electrode elements, wherein at least two of the separate electrode elements are differentially interconnected.

14. The MEMS mirror device (100) according to any one of the preceding claims, wherein the respective glass materials of at least two interconnected ones of the glass substrates (120; 145) have a thermal expansion coefficient that is the same or differs by no more than 10⁻⁴ K⁻¹.

15. The MEMS mirror device (100) according to any one of the preceding claims, further comprising a drive device (105; 260; 310; 315) adapted to impart multi-dimensional oscillatory motion to the mirror subregion (130) relative to the frame subregion (125).

16. The MEMS mirror device (100) according to claim 15, wherein the mirror subregion (130) is suspended for oscillation relative to the frame subregion (125) such that, when appropriately excited by the drive device (105; 260; 315), the mirror subregion performs the multi-dimensional oscillatory motion in the form of a Lissajous oscillatory motion.

17. The MEMS mirror device (100; 1300; 1900) according to claim 15 or 16, wherein the drive device comprises a piezo-actuator (260; 315) indirectly mechanically coupled to the first glass substrate (120) via at least one of the other one or more glass substrates.

18. The MEMS mirror device (100; 1900) according to any one of the preceding claims, wherein: the mirror subregion (130) includes a metallic layer (140; 240) formed at least in part as a mirror surface for deflecting the electromagnetic beam; and
the metallic layer (140; 240) includes one or more of the following metallic materials: aluminum, gold, silver.

19. The MEMS mirror device (200) according to any one of claims 2 to 18, wherein at least one side of the second glass substrate (120) is coated with metal over its entire surface.

20. The MEMS mirror device (800) according to any one of the preceding claims, further comprising a separate housing (220; 225) for housing the connected substrates (120; 115) of the MEMS mirror device.

21. The MEMS mirror device (1000) according to any one of the preceding claims, wherein the mirror subregion (130) or the frame subregion (125) are thickened in thickness by bonding to at least one further substrate (230).

22. The Method (2000) for producing a MEMS mirror device (100), wherein the method comprises:
simultaneously forming (2005 to 2050) a plurality of similar MEMS mirror devices (100) according to any one of the preceding claims using at least one disk-shaped glass substrate (120) common to all of said MEMS mirror devices (110); and
separating (2055) the MEMS mirror devices according to their simultaneous formation.

23. The Method (2000) according to claim 22, wherein the common disk-shaped glass substrate (120) is a glass substrate that has a rectangular disk shape prior to singulation.

24. The Method (2000) according to claim 22 or 23, wherein the respective first glass substrate (120) of the individual MEMS mirror devices (100) emerges from the common glass substrate by the patterning thereof using at least one glass patterning process.

25. The Method (2000) according to any one of claims 22 to 24, wherein a patterning of the common glass substrate (120) or at least one other of the substrates (110, 115, 145) respectively present in the MEMS mirror devices is performed using a laser-based etching method.

26. The Method (2000) according claim 25, wherein the patterning of the common glass substrate (120) or at least one other of the substrates (110, 115, 145) respectively present in the MEMS mirror devices (100) is performed using a laser-induced chemical etching method.
